(19) United States
(12) Patent Application Publication
(10) Pub. No.: US 2025/0210475 A1
(43) Pub. Date: Jun. 26, 2025

(54) SEMICONDUCTOR DEVICE

(71) Applicant: Rohm Co., Ltd., Kyoto-shi (JP)

(72) Inventors: Ryotaro KAKIZAKI, Kyoto-shi (JP); Koshun SAITO, Kyoto-shi (JP)

(21) Appl. No.: 19/076,503

(22) Filed: Mar. 11, 2025

Related U.S. Application Data
(63) Continuation of application No. PCT/JP2023/030130, filed on Aug. 22, 2023.

(30) Foreign Application Priority Data
Sep. 14, 2022 (JP) 2022-146346

(51) Int. Cl. H01L 23/495; H01L 23/00; H01L 23/31; H01L 25/07

(52) U.S. Cl. CPC H01L 23/49555; H01L 23/3107; H01L 23/49513; H01L 24/45; H01L 24/48; H01L 25/072; H01L 2224/45014; H01L 2224/48247

(57) ABSTRACT

A semiconductor device includes a semiconductor element, a first lead including a die pad portion, the die pad portion including a first lead obverse surface facing a first side in a thickness direction and carrying the semiconductor element, a first lead reverse surface facing a second side in the thickness direction, and a first lead side surface facing a first side in a first direction; a second lead apart from the die pad portion toward the first side in the first direction; and a wire conductively bonded to the semiconductor element and the second lead. The die pad portion includes a contact avoidance surface connected to the first lead obverse surface and the first lead side surface. The contact avoidance surface overlaps with the wire as viewed in the thickness direction, and is located on the second side in the thickness direction with respect to the first lead obverse surface.

### TECHNICAL FIELD

The present disclosure relates to a semiconductor device.

### BACKGROUND ART

JP-A-2020-038914 discloses a semiconductor device provided with a first lead, a third lead, a semiconductor element, a bonding wire, and a sealing resin. The semiconductor element is mounted on a mounting portion of the third lead and connected to the first lead by a bonding wire. The sealing resin covers a portion of each lead, the semiconductor element, and the bonding wire. In the semiconductor device, a mounting portion obverse surface of the mounting portion on which the semiconductor element is mounted and a wire bonding obverse surface of the first lead to which the bonding wire is connected are at the same position in a z direction (a thickness direction). In the semiconductor device, it is conceivable to increase the diameter of the bonding wire in order to carry a large current. In addition, it is required to thinner semiconductor devices. In the above semiconductor device, if the semiconductor element is made thinner and the thickness dimension of the sealing resin is made smaller, the loop of the bonding wire becomes lower, which may cause the bonding wire to contact the mounting portion.

### BRIEF DESCRIPTION OF THE DRAWINGS

FIG. 1 is a perspective view of a semiconductor device according to a first embodiment of the present disclosure.

FIG. 2 is a perspective view of the semiconductor device according to the first embodiment of the present disclosure.

FIG. 3 is a perspective view of the semiconductor device according to the first embodiment of the present disclosure.

FIG. 4 is a perspective view showing relevant portions of the semiconductor device according to the first embodiment of the present disclosure.

FIG. 5 is a perspective view showing relevant portions of the semiconductor device according to the first embodiment of the present disclosure.

FIG. 6 is a plan view of the semiconductor device according to the first embodiment of the present disclosure.

FIG. 7 is a bottom view of the semiconductor device according to the first embodiment of the present disclosure.

FIG. 8 is a front view of the semiconductor device according to the first embodiment of the present disclosure.

FIG. 9 is a side view of the semiconductor device according to the first embodiment of the present disclosure.

FIG. 10 is a plan view showing relevant portions of the semiconductor device according to the first embodiment of the present disclosure.

FIG. 11 is a bottom view showing relevant portions of the semiconductor device according to the first embodiment of the present disclosure.

FIG. 12 is a cross-sectional view along a line XII-XII of FIG. 11.

FIG. 13 is an enlarged view of FIG. 12.

FIG. 14 is a cross-sectional view along a line XIV-XIV of FIG. 11.

FIG. 15 is a cross-sectional view along a line XV-XV of FIG. 11.

FIG. 16 is a cross-sectional view along a line XVI-XVI of FIG. 11.

FIG. 17 is a cross-sectional view showing a state of use of the semiconductor device according to the first embodiment of the present disclosure.

FIG. 18 is an enlarged cross-sectional view showing a first variation of the semiconductor device according to the first embodiment of the present disclosure.

FIG. 19 is an enlarged cross-sectional view showing a second variation of the semiconductor device according to the first embodiment of the present disclosure.

FIG. 20 is an enlarged cross-sectional view showing a third variation of the semiconductor device according to the first embodiment of the present disclosure.

FIG. 21 is an enlarged cross-sectional view showing a fourth variation of the semiconductor device according to the first embodiment of the present disclosure.

FIG. 22 is an enlarged cross-sectional view showing a fifth variation of the semiconductor device according to the first embodiment of the present disclosure.

FIG. 23 is a bottom view showing relevant portions of a sixth variation of the semiconductor device according to the first embodiment of the present disclosure.

FIG. 24 is a cross-sectional view showing a semiconductor device according to a second embodiment of the present disclosure.

FIG. 25 is a cross-sectional view showing a state of use of the semiconductor device according to the second embodiment of the present disclosure.

FIG. 26 is a perspective view showing a semiconductor device according to a third embodiment of the present disclosure.

FIG. 27 is a cross-sectional view showing the semiconductor device according to the third embodiment of the present disclosure.

FIG. 28 is a perspective view showing a semiconductor device according to a fourth embodiment of the present disclosure.

FIG. 29 is a cross-sectional view showing the semiconductor device according to the fourth embodiment of the present disclosure.

FIG. 30 is a perspective view showing a semiconductor device according to a fifth embodiment of the present disclosure.

FIG. 31 is a cross-sectional view showing the semiconductor device according to the fifth embodiment of the present disclosure.

FIG. 32 is a cross-sectional view showing a semiconductor device according to a sixth embodiment of the present disclosure.

FIG. 33 is a bottom view showing relevant portions of a semiconductor device according to a seventh embodiment of the present disclosure.

FIG. 34 is a bottom view showing relevant portions of a semiconductor device according to an eighth embodiment of the present disclosure.

FIG. 35 is a cross-sectional view along a line XXXV-XXXV of FIG. 34.

FIG. 36 is a cross-sectional view showing a semiconductor device according to a ninth embodiment of the present disclosure.

FIG. 37 is a perspective view showing a semiconductor device according to a tenth embodiment of the present disclosure.

FIG. 38 is a bottom view showing relevant portions of the semiconductor device according to the tenth embodiment of the present disclosure.

FIG. 39 is a cross-sectional view showing a semiconductor device according to an eleventh embodiment of the present disclosure.

FIG. 40 is a cross-sectional view showing a semiconductor device according to a twelfth embodiment of the present disclosure.

### DETAILED DESCRIPTION OF EMBODIMENTS

Preferred embodiments of the present disclosure are specifically described below with reference to the accompanying drawings.

The terms such as “first,” “second,” and “third,” in the present disclosure are used merely as labels and not intended to impose orders on the elements accompanied with these terms.

In the present disclosure, the expression “An object A is formed in an object B”, and “An object A is formed on an object B” imply the situation where, unless otherwise specifically noted, “the object A is formed directly in or on the object B”, and “the object A is formed in or on the object B, with something else interposed between the object A and the object B”. Likewise, the expression “An object A is disposed in an object B”, and “An object A is disposed on an object B” imply the situation where, unless otherwise specifically noted, “the object A is disposed directly in or on the object B”, and “the object A is disposed in or on the object B, with something else interposed between the object A and the object B”. Further, the expression “An object A is located on an object B” implies the situation where, unless otherwise specifically noted, “the object A is located on the object B, in contact with the object B”, and “the object A is located on the object B, with something else interposed between the object A and the object B”. Still further, the expression “An object A overlaps with an object B as viewed in a certain direction” implies the situation where, unless otherwise specifically noted, “the object A overlaps with the entirety of the object B”, and “the object A overlaps with a portion of the object B”.

### First Embodiment

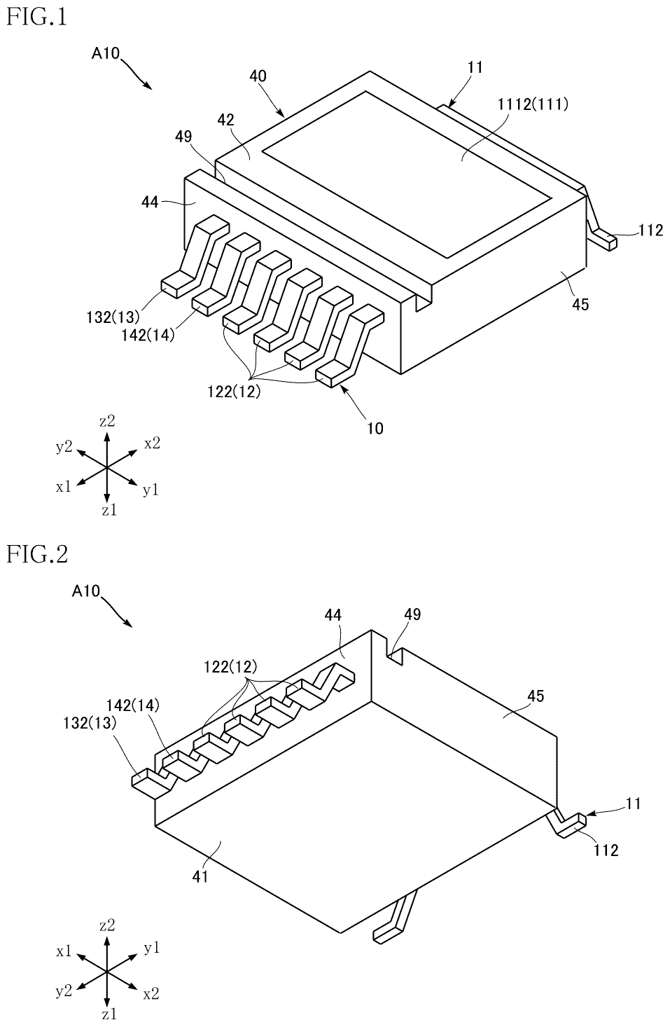

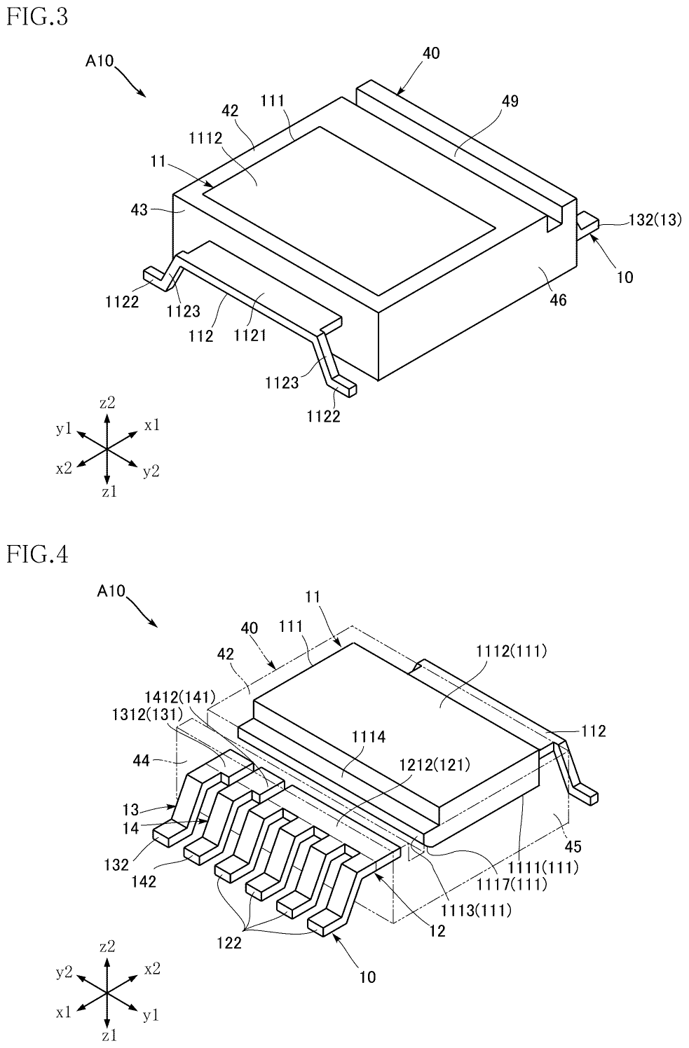

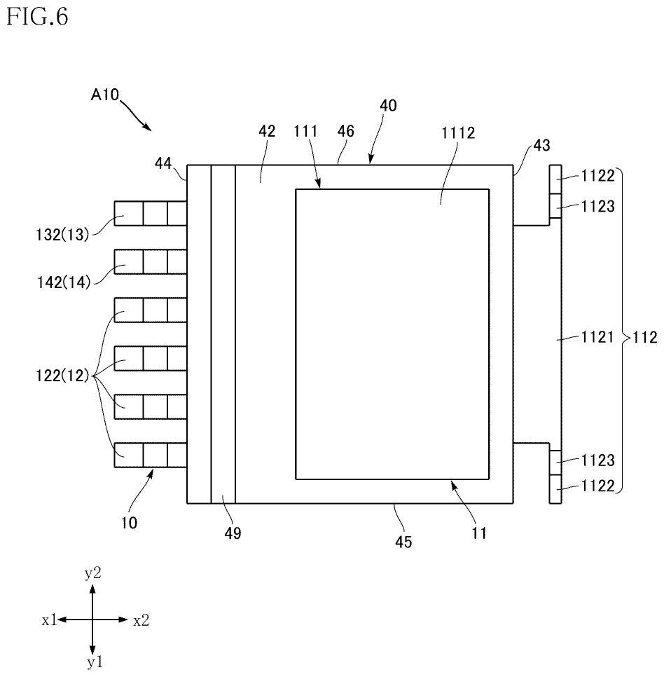

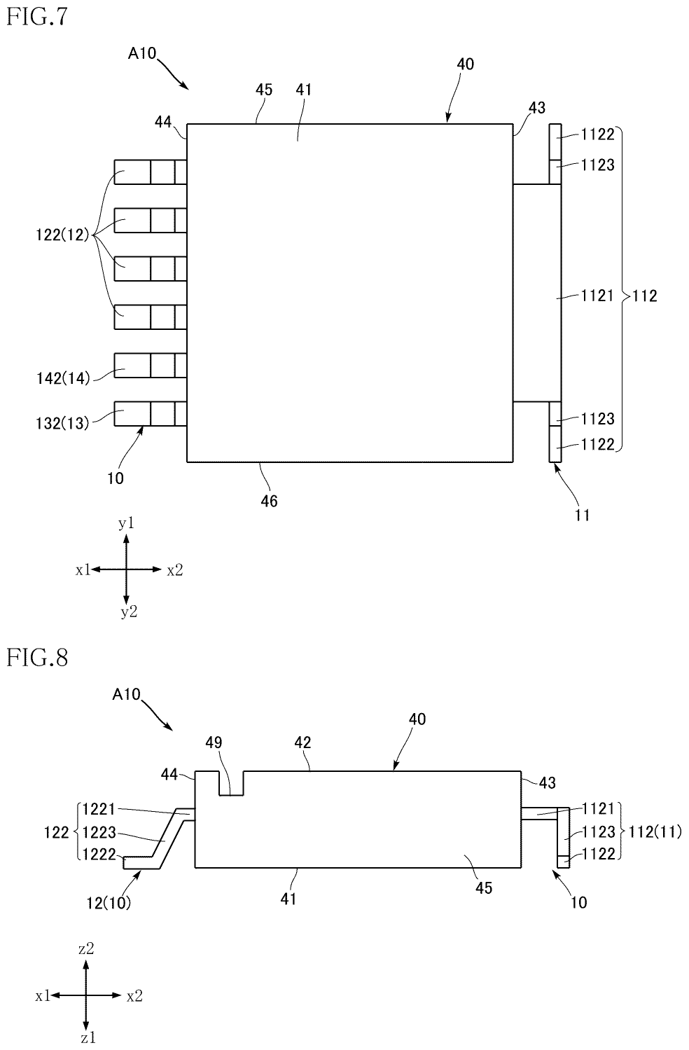

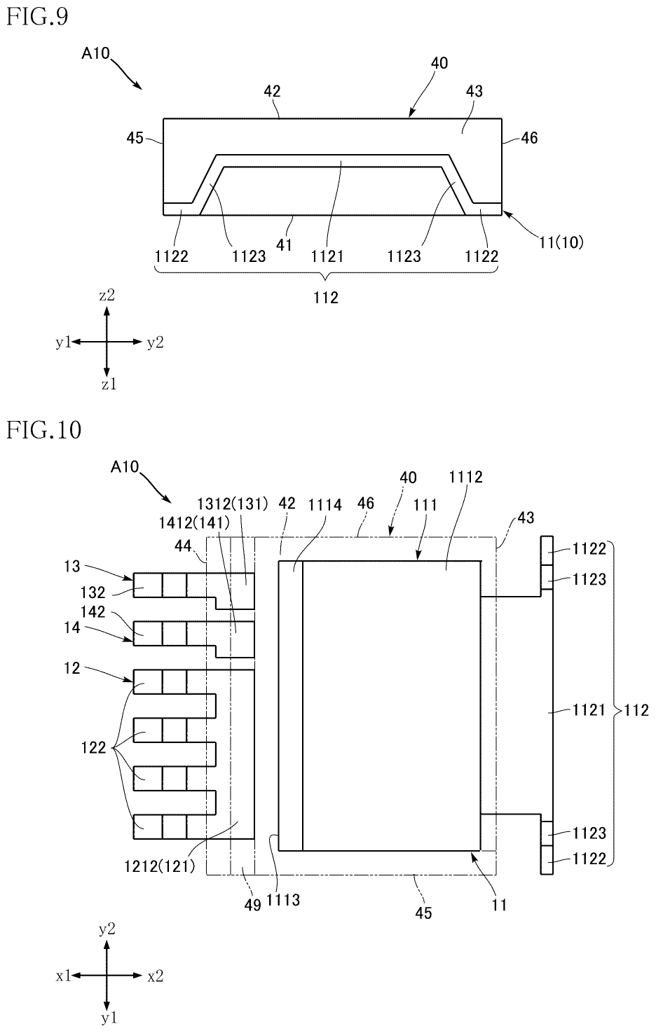

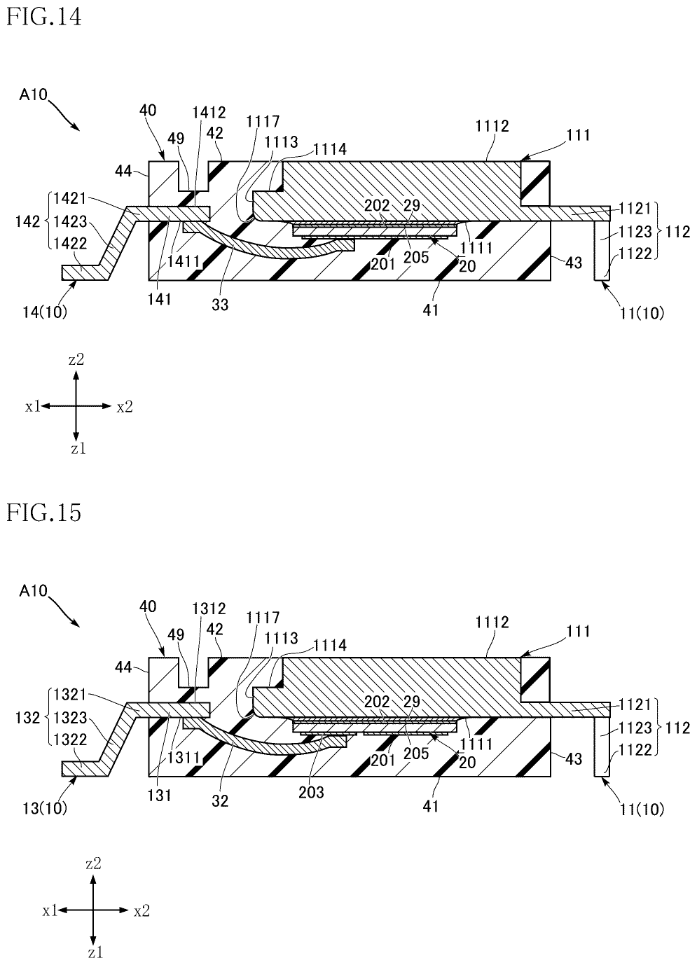

FIGS. 1 to 16 show a semiconductor device according to a first embodiment of the present disclosure. A semiconductor device A10 of the present embodiment has a conductive member 10, semiconductor elements 20 and 25, connecting members 31, 32, 33 and 34, and a scaling resin 40. The semiconductor device A10 is rectangular as viewed in a thickness direction (in a plan view). For convenience of explanation, the thickness direction (a plan view direction) of the semiconductor device A10 is designated as a thickness direction z. A direction along one side of the semiconductor device A10 orthogonal to the thickness direction z (left and right directions in FIGS. 6 and 7) is designated as a first direction x, and a direction orthogonal to the thickness direction z and the first direction x (upper and lower directions in FIGS. 6 and 7) is designated as a second direction y. Further, it is provided that one side of the thickness direction z (the lower side in FIGS. 8 and 9) is a first side z1, and the other side (the upper side in FIGS. 8 and 9) is a second side z2. It is provided that one side of the first direction x (the left side in FIGS. 6 and 7) is a first side x1 and the other side (the right side in FIGS. 6 and 7) is a second side x2. It is provided that one side of the second direction y (the lower side in FIG. 6) is a first side y1, and the other side (the upper side in FIG. 6) is a second side y2. Note that the shape and the respective dimensions of the semiconductor device A10 are not limited.

### Conductive Member 10

The conductive member 10 is a member that constitutes a conduction path to the semiconductor elements 20 and 25. The conductive member 10 according to the present embodiment includes a first lead 11, a second lead 12, a third lead 13 and a fourth lead 14. The materials of the first lead 11, the second lead 12, the third lead 13, and the fourth lead 14 are not limited in any way, and contain, for example, copper (Cu) or a copper alloy. Further, the first lead 11, the second lead 12, the third lead 13, and the fourth lead 14 may be plated with silver (Ag), nickel (Ni), tin (Sn), or the like at appropriate locations.

### First Lead 11

As shown in FIGS. 1 to 17, the first lead 11 has a die pad portion 111 and a first terminal portion 112. The die pad portion 111 has a first lead obverse surface 1111 and a first lead reverse surface 1112. The first lead obverse surface 1111 is a surface facing the first side z1 in the thickness direction z. The first lead reverse surface 1112 is a surface facing the second side z2 in the thickness direction z. The first lead obverse surface 1111 has a semiconductor element 20 mounted thereon.

The die pad portion 111 of the present embodiment further has a first lead side surface 1113, a first intermediate surface 1114, and a contact avoidance surface 1117. The first lead side surface 1113 is located between the first lead obverse surface 1111 and the first lead reverse surface 1112 in the thickness direction z and is a surface facing the first side x1 in the first direction x. The first intermediate surface 1114 is located between the first lead obverse surface 1111 and the first lead reverse surface 1112 in the thickness direction z and is a surface facing the second side z2 in the thickness direction z (the same side as the first lead reverse surface 1112 faces).

The contact avoidance surface 1117 is located between the first lead obverse surface 1111 and the first lead reverse surface 1112 in the thickness direction z and is connected to the first lead obverse surface 1111 and the first lead side surface 1113. That is, the contact avoidance surface 1117 is a surface in the die pad portion 111 that is located on the first side z1 in the thickness direction z and on the first side x1 in the first direction x. The contact avoidance surface 1117 is located on the second side z2 in the thickness direction z with respect to the first lead obverse surface 1111. In the present embodiment, the contact avoidance surface 1117 extends to the respective peripheral ends in the second direction y of the die pad portion 111 and is a curvature that is convex outwardly.

The shape of the die pad portion 111 is not limited in any way. In the illustrated example, the die pad portion 111 is rectangular as viewed in the thickness direction z. Further, the shapes of the first lead obverse surface 1111 and the first lead reverse surface 1112 are not limited in any way, and in the illustrated example, they are rectangular as viewed in the thickness direction z.

The first terminal portion 112 is curved toward the first side z1 in the thickness direction z and has a first section 1121, two second sections 1122 and two third sections 1123.

The first section 1121 is connected to the die pad portion 111 and extends from the die pad portion 111 to the second side x2 in the first direction x, which in the illustrated example is parallel (or substantially parallel) to the xy plane. In the present embodiment, the die pad portion 111 is larger in the thickness direction z than the first section 1121. The first terminal portion 112 of the present embodiment has only one first section 1121. The shape of the first section 1121 is not limited in any way, and in the illustrated example, it is rectangular as viewed in the thickness direction z. The first section 1121 is separated from the first lead reverse surface 1112 in the thickness direction z, and in the illustrated example, it is continuous to the first lead obverse surface 1111. One side of the first section 1121 is flush with the first lead obverse surface 1111.

The two second sections 1122 are located on the first side z1 in the thickness direction z with respect to the first section 1121. The two second sections 1122 are used when surface-mounting the semiconductor device A10 on a circuit substrate or the like.

The two third sections 1123 are interposed between the first section 1121 and the two second sections 1122. The third sections 1123 extend from the first section 1121 to the first side z1 in the thickness direction z. In the illustrated example, the third sections 1123 are inclined with respect to the thickness direction z to extend outwardly in the second direction y from the first section 1121. The shape of the third sections 1123 is not limited in any way, and in the illustrated example it is rectangular as viewed in the first direction x.

In the present embodiment, the two second sections 1122 extend outwardly in the second direction y from the two third sections 1123. Further, the two second sections 1122 are parallel (or substantially parallel) to the second direction y. The two second sections 1122 do not extend farther than the two third sections 1123 to the second side x2 in the first direction x. In the illustrated example, the two second sections 1122 and the two third sections 1123 are at the same (or substantially the same) position in the first direction x.

### Second Lead 12

The second lead 12 is arranged apart from the first lead 11 and is located on the first side x1 in the first direction x with respect to the die pad portion 111. The second lead 12 has a second pad portion 121 and a plurality of second terminal portions 122.

The second pad portion 121 has a second lead obverse surface 1211 and a second lead reverse surface 1212. The second lead obverse surface 1211 is a surface facing the first side z1 in the thickness direction z. The second lead reverse surface 1212 is a surface facing the second side z2 in the thickness direction z. In the present embodiment, the second lead obverse surface 1211 is at the same (or substantially the same) position as the first lead obverse surface 1111 in the thickness direction z. A connecting member 31 is conductively bonded to the second lead obverse surface 1211. The shape of the second pad portion 121 is not limited in any way, and in the illustrated example, it has a long rectangular shape where the second direction y is the longitudinal direction. Further, as viewed in the thickness direction z, the second pad portion 121 is smaller than the die pad portion 111. Moreover, the second pad portion 121 is smaller in size in the thickness direction z than the die pad portion 111, and is the same (or substantially the same) as the first section 1121 of the first terminal portion 112.

The plurality of second terminal portions 122 are arranged in line in the second direction y. The second terminal portions 122 are curved toward the first side z1 in the thickness direction z and have a fourth section 1221, a fifth section 1222 and a sixth section 1223.

The fourth section 1221 is connected to the second pad portion 121 and extends from the second pad portion 121 to the first side x1 in the first direction x, and in the illustrated example it is parallel (or substantially parallel) to the xy plane. The surface of the fourth section 1221 facing the first side z1 in the thickness direction z is flush with the second lead obverse surface 1211. The shape of the fourth section 1221 is not limited in any way, and in the illustrated example it is rectangular as viewed in the thickness direction z.

The fifth section 1222 is located on the first side z1 in the thickness direction z with respect to the fourth section 1221. The fifth section 1222 is used when the semiconductor device A10 is surface-mounted on a circuit substrate or the like. The fifth section 1222 is shaped to extend along the first direction x.

The sixth section 1223 is interposed between the fourth section 1221 and the fifth section 1222. The sixth section 1223 extends from the fourth section 1221 to the first side z1 in the thickness direction z. In the illustrated example, the sixth section 1223 is inclined with respect to the thickness direction z (the yz plane). The shape of the sixth section 1223 is not limited in any way, and in the illustrated example it is rectangular as viewed in the first direction x.

### Third Lead 13

The third lead 13 is arranged apart from the first lead 11 and the second lead 12 and is located on the first side x1 in the first direction x with respect to the die pad portion 111. Further, the third lead 13 is aligned with the second lead 12 in the second direction y. The third lead 13 has a third pad portion 131 and a third terminal portion 132.

The third pad portion 131 has a third lead obverse surface 1311 and a third lead reverse surface 1312. The third lead obverse surface 1311 is a surface facing the first side z1 in the thickness direction z. The third lead reverse surface 1312 is a surface facing the second side z2 in the thickness direction z. In the present embodiment, the third lead obverse surface 1311 is at the same (or substantially the same) position as the first lead obverse surface 1111 in the thickness direction z. The connecting member 32 is conductively bonded to the third lead obverse surface 1311. The shape of the third pad portion 131 is not limited in any way, and in the illustrated example it is rectangular as viewed in the thickness direction z. Further, as viewed in the thickness direction z, the third pad portion 131 is smaller than the second pad portion 121. Moreover, the third pad portion 131 is smaller in size in the thickness direction z than the die pad portion 111, and is the same (or substantially the same) as the second pad portion 121.

The third terminal portion 132 is curved toward the first side z1 in the thickness direction z and has a seventh section 1321, an eighth section 1322 and a ninth section 1323.

The seventh section 1321 is connected to the third pad portion 131 and extends from the third pad portion 131 to the first side x1 in the first direction x, and in the illustrated example it is parallel (or substantially parallel) to the xy plane. The surface of the seventh section 1321 facing the first side z1 in the thickness direction z is flush with the third lead obverse surface 1311. The shape of the seventh section 1321 is not limited in any way, and in the illustrated example it is rectangular as viewed in the thickness direction z.

The eighth section 1322 is located on the first side z1 in the thickness direction z with respect to the seventh section 1321. The eighth section 1322 is used when the semiconductor device A10 is surface-mounted on a circuit substrate or the like. The eighth section 1322 is shaped to extend along the first direction x.

The ninth section 1323 is interposed between the seventh section 1321 and the eighth section 1322. The ninth section 1323 extends from the seventh section 1321 to the first side z1 in the thickness direction z. In the illustrated example, the ninth section 1323 is inclined with respect to the thickness direction z (the yz plane). The shape of the ninth section 1323 is not limited in any way, and in the illustrated example it is rectangular as viewed in the first direction x.

### Fourth Lead 14

The fourth lead 14 is arranged apart from the first lead 11, the second lead 12 and the third lead 13 and is located on the first side x1 in the first direction x with respect to the die pad portion 111. Further, the fourth lead 14 is located between the second lead 12 and the third lead 13 in the second direction y. The fourth lead 14 has a fourth pad portion 141 and a fourth terminal portion 142.

The fourth pad portion 141 has a fourth lead obverse surface 1411 and a fourth lead reverse surface 1412. The fourth lead obverse surface 1411 is a surface facing the first side z1 in the thickness direction z. The fourth lead reverse surface 1412 is a surface facing the second side z2 in the thickness direction z. In the present embodiment, the fourth lead obverse surface 1411 is at the same (or substantially the same) position as the first lead obverse surface 1111 in the thickness direction z. The connecting member 33 is conductively bonded to the fourth lead obverse surface 1411. The shape of the fourth pad portion 141 is not limited in any way, and in the illustrated example it is rectangular as viewed in the thickness direction z. Further, as viewed in the thickness direction z, the fourth pad portion 141 is smaller than the second pad portion 121 and has substantially the same size as the third pad portion 131. Moreover, the fourth pad portion 141 is smaller in size in the thickness direction z than the die pad portion 111 and is the same (or substantially the same) as the second pad portion 121 and the third pad portion 131.

The fourth terminal portion 142 is curved toward the first side z1 in the thickness direction z and has a tenth section 1421, an eleventh section 1422 and a twelfth section 1423.

The tenth section 1421 is connected to the fourth pad portion 141 and extends from the fourth pad portion 141 to the first side x1 in the first direction x, and in the illustrated example it is parallel (or substantially parallel) to the xy plane. The surface of the tenth section 1421 facing the first side z1 in the thickness direction z is flush with the fourth lead obverse surface 1411. The shape of the tenth section 1421 is not limited in any way, and in the illustrated example it is rectangular as viewed in the thickness direction z.

The eleventh section 1422 is located on the first side z1 in the thickness direction z with respect to the tenth section 1421. The eleventh section 1422 is used when the semiconductor device A10 is surface-mounted on a circuit substrate or the like. The eleventh section 1422 is shaped to extend along the first direction x.

The twelfth section 1423 is interposed between the tenth section 1421 and the eleventh section 1422. The twelfth section 1423 extends from the tenth section 1421 to the first side z1 in the thickness direction z. In the illustrated example, the twelfth section 1423 is inclined with respect to the thickness direction z (the yz plane). The shape of the twelfth section 1423 is not limited in any way, and in the illustrated example it is rectangular as viewed in the first direction x.

### Semiconductor Element 20

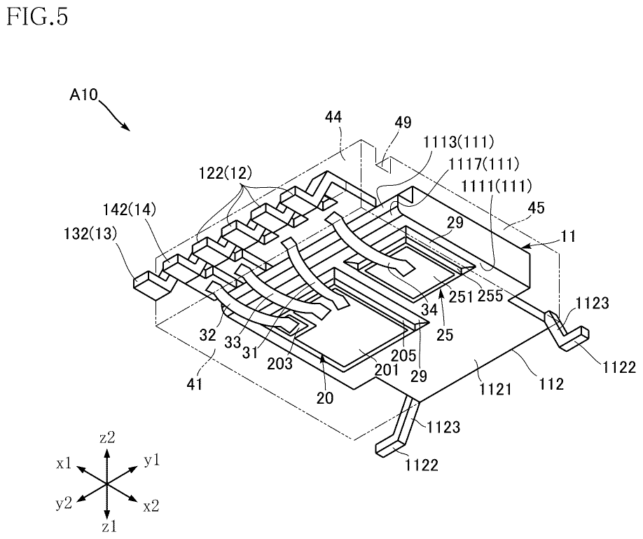

The semiconductor element 20 is mounted on the first lead obverse surface 1111 of the die pad portion 111, as shown in FIG. 5 and FIGS. 11 to 17. In the semiconductor device A10, the semiconductor element 20 is a switching element. The switching element is, for example, of an n-channel type and is a MOSFET (Metal-Oxide-Semiconductor Field-Effect Transistor) of a vertical structure. The semiconductor element 20 is not limited to a MOSFET. The semiconductor clement 20 may be another transistor such as an IGBT (Insulated Gate Bipolar Transistor). The semiconductor element 20 has a semiconductor layer 205, a first electrode 201, a second electrode 202 and a third electrode 203.

The semiconductor layer 205 includes a compound semiconductor substrate. The main material of the compound semiconductor substrate is silicon carbide (SiC). In addition, silicon (Si) may be used as the main material of the compound semiconductor substrate.

The first electrode 201 is provided on the first side z1 in the thickness direction z (the side toward which the first lead obverse surface 1111 faces in the thickness direction z) in the semiconductor layer 205. The first electrode 201 corresponds to the source electrode of the semiconductor element 20.

The second electrode 202 is provided on a side opposite to the first electrode 201 in the thickness direction z. The second electrode 202 is opposed to the first lead obverse surface 1111 of the die pad portion 111 of the first lead 11. The second electrode 202 corresponds to the drain electrode of the semiconductor element 20. In the present embodiment, the second electrode 202 is conductively bonded to the first lead obverse surface 1111 with an intervention of the bonding layer 29. The bonding layer 29 is, for example, solder, silver (Ag) paste, sintered silver, and the like.

The third electrode 203 is provided on the same side as the first electrode 201 in the thickness direction z and is positioned apart from the first electrode 201. The third electrode 203 corresponds to the gate electrode of the semiconductor element 20. As viewed in the thickness direction z, the area of the third electrode 203 is smaller than the area of the first electrode 201.

### Semiconductor Element 25

The semiconductor element 25 is mounted on the first lead obverse surface 1111 of the die pad portion 111. The semiconductor element 25 is arranged on the first side y1 in the second direction y of the semiconductor element 20. In the semiconductor device A10, the semiconductor element 25 is a diode. The semiconductor element 25 has a semiconductor layer 255, a first electrode 251 and a second electrode 252.

The semiconductor layer 255 includes a compound semiconductor substrate. The main material of the compound semiconductor substrate is silicon carbide (SiC). In addition, silicon (Si) may be used as the main material of the compound semiconductor substrate.

The first electrode 251 is provided on the first side z1 in the thickness direction z (the side toward which the first lead obverse surface 1111 faces in the thickness direction z) of the semiconductor layer 255. The first electrode 251 corresponds to the anode electrode of the semiconductor element 25.

The second electrode 252 is arranged on a side opposite to the first electrode 251 in the thickness direction z. The second electrode 252 is opposed to the first lead obverse surface 1111 of the die pad portion 111 of the first lead 11. The second electrode 252 corresponds to the cathode electrode of the semiconductor element 25. In the present embodiment, the second electrode 252 is conductively bonded to the first lead obverse surface 1111 with an intervention of the bonding layer 29.

### Connecting Members 31, 32, 33 and 34

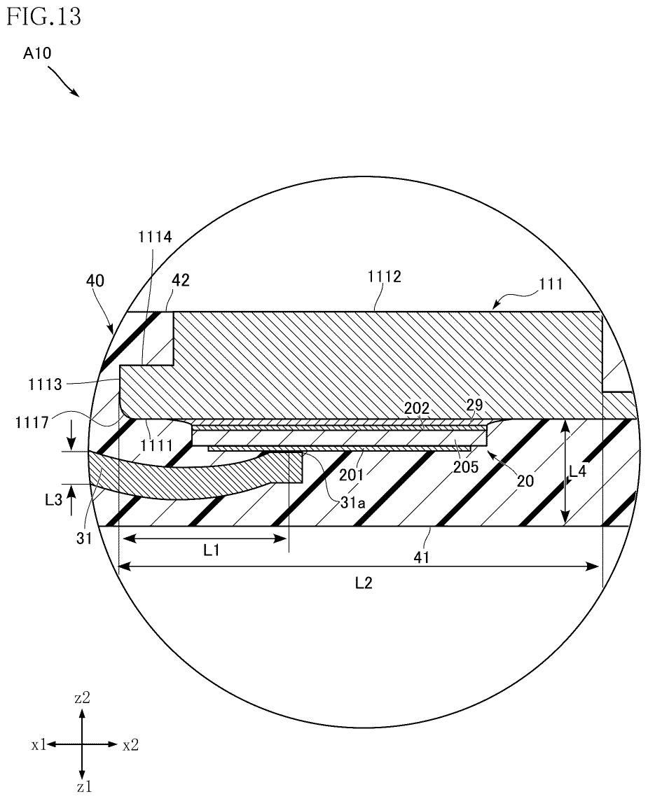

The connecting member 31 is conductively bonded to the first electrode 201 of the semiconductor element 20 and the second lead obverse surface 1211 of the second pad portion 121 of the second lead 12. The material of the connecting member 31 is not limited in any way and contains metal such as aluminum (Al), copper (Cu) and gold (Au). In the present embodiment, the connecting member 31 is a wire containing aluminum (Al) and has a relatively large diameter to carry a large current. The diameter of the connecting member 31 is not limited, but is about 400 to 500 μm, for example. Note that the number of connecting members 31 is not limited in any way, and a plurality of connecting members 31 may be provided. As shown in FIG. 13, in the first direction x, a distance L1 between the bonding position 31a of the connecting member 31 with the semiconductor element 20 and the first lead side surface 1113 is relatively large, and for example, it is equal to or more than one third of a dimension L2 of the first lead obverse surface 1111. Note that the distance L1 is not limited to this.

The connecting member 32 is conductively bonded to the third electrode 203 of the semiconductor element 20 and the third lead obverse surface 1311 of the third pad portion 131 of the third lead 13. The material and diameter of the connecting member 32 are not limited in any way, but in the present embodiment, the same wire as the connecting member 31 is used.

The connecting member 33 is conductively bonded to the first electrode 201 of the semiconductor element 20 and the fourth lead obverse surface 1411 of the fourth pad portion 141 of the fourth lead 14. The material and diameter of the connecting member 33 are not limited in any way, but in the present embodiment, the same wire as the connecting member 31 is used.

The connecting member 34 is conductively bonded to the first electrode 251 of the semiconductor element 25 and the second lead obverse surface 1211 of the second pad portion 121 of the second lead 12. The material and diameter of the connecting member 34 are not limited in any way, but in the present embodiment, the same wire as the connecting member 31 is used.

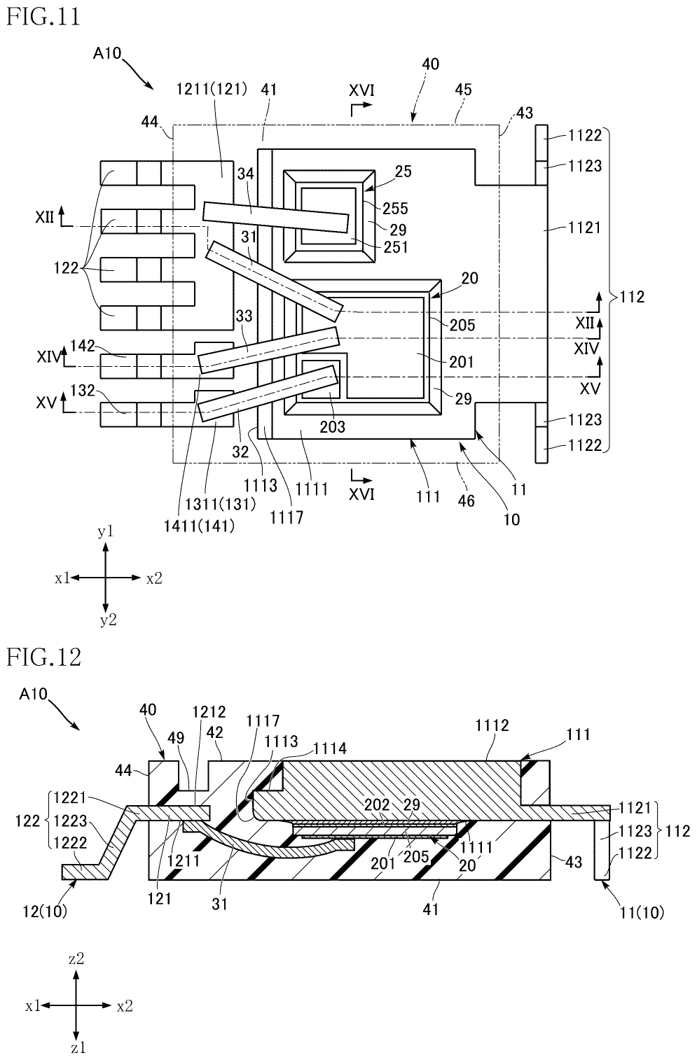

As shown in FIGS. 5 and 11, all of the connecting members 31 to 34 overlap the contact avoidance surface 1117 as viewed in the thickness direction z. In the present embodiment, the first terminal portion 112 of the first lead 11 is a drain terminal, the second terminal portions 122 of the second leads 12 are source terminals, the third terminal portion 132 of the third lead 13 is a gate terminal, and the fourth terminal portion 142 of the fourth lead 14 is a source sense terminal.

### Sealing Resin 40

As shown in FIGS. 1 to 17, the sealing resin 40 covers the semiconductor elements 20 and 25, the connecting members 31, 32, 33 and 34, and a part of each of the first lead 11, the second lead 12, the third lead 13 and the fourth lead 14. The sealing resin 40 has electrical insulation properties. The sealing resin 40 is composed of a material including, for example, a black epoxy resin. The sealing resin 40 has a first resin surface 41, a second resin surface 42, a third resin surface 43, a fourth resin surface 44, a fifth resin surface 45 and a sixth resin surface 46.

The first resin surface 41 faces the first side z1 in the thickness direction z (the same side the first lead obverse surface 1111 faces in the thickness direction z). As shown in FIG. 13, a distance L4 between the first resin surface 41 and the first lead obverse surface 1111 (a thickness dimension of the sealing resin 40 on the first lead obverse surface 1111) is relatively small, and for example, it is equal to or less than four times a diameter L3 of the connecting members 31 to 34. Note that the distance L4 is not limited to this. The second resin surface 42 faces the second side z2 in the thickness direction (opposite to the side the first resin surface 41 faces in the thickness direction z). From the second resin surface 42, the first lead reverse surface 1112 of the die pad portion 111 of the first lead 11 is exposed. The second resin surface 42 and the first lead reverse surface 1112 are flush with each other. The first lead reverse surface 1112 is separated from the third resin surface 43 in the first direction x.

The third resin surface 43 faces the second side x2 in the first direction x. The first section 1121 of the plurality of first terminal portions 112 of the first lead 11 penetrates the third resin surface 43. Further, the first section 1121 is separated from the second resin surface 42 in the thickness direction z.

The fourth resin surface 44 faces the first side x1 in the first direction x (opposite to the side the third resin surface 43 faces in the first direction x). In the present embodiment, the fourth sections 1221 of the plurality of second terminal portions 122 of the second lead 12, the seventh section 1321 of the third terminal portion 132 of the third lead 13, and the tenth section 1421 of the fourth terminal portion 142 of the fourth lead 14 penetrate the fourth resin surface 44. Further, the fourth sections 1221, the seventh section 1321, and the tenth section 1421 are separated from the second resin surface 42 in the thickness direction z.

The fifth resin surface 45 and the sixth resin surface 46 are surfaces facing oppositely to each other in the second direction y.

In the illustrated example, the sealing resin 40 has a groove 49. The groove 49 is recessed in the thickness direction z from the second resin surface 42 and extends along the second direction y. The groove 49 reaches the fifth resin surface 45 and the sixth resin surface 46.

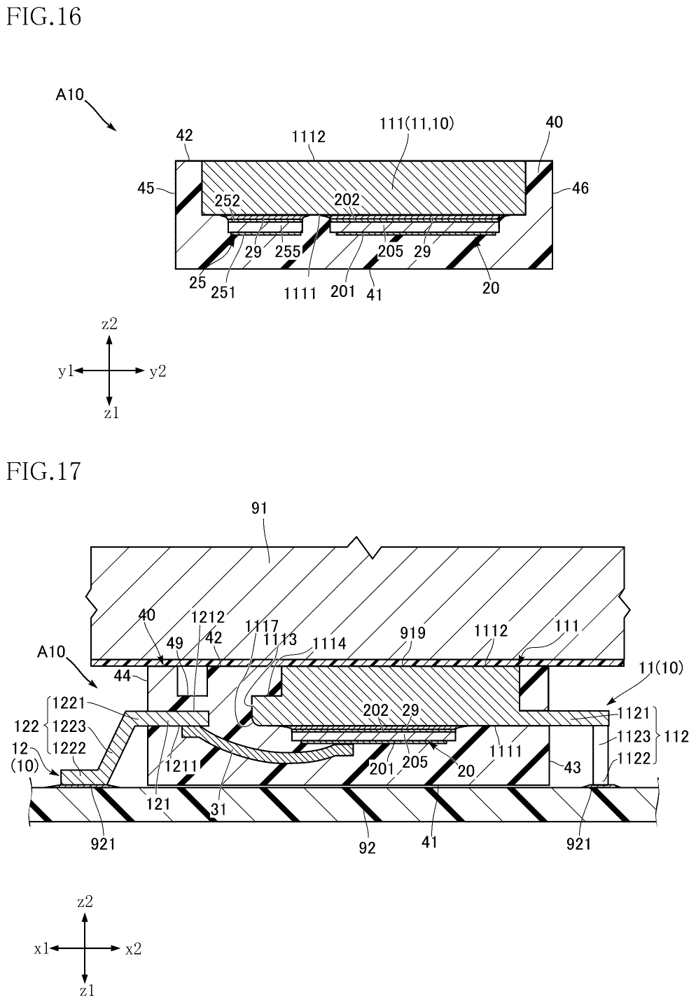

FIG. 17 shows a state of use of the semiconductor device A10. In this use example, the semiconductor device A10 is surface-mounted on the circuit substrate 92. That is, the second sections 1122 of the first terminal portion 112, the fifth sections 1222 of the second terminal portions 122, the eighth section 1322 of the third terminal portion 132, and the eleventh section 1422 of the fourth terminal portion 142 are conductively bonded to a wiring pattern (not shown) of the circuit substrate 92 by solder 921 for example. Further, a heat sink 91 is arranged opposed to the first lead reverse surface 1112 of the die pad portion 111. In the illustrated example, a sheet material 919 is arranged between the first lead reverse surface 1112 and the heat sink 91. The sheet material 919 is, for example, an insulating sheet.

Next, functions of the semiconductor device A10 will be described.

According to the present embodiment, the die pad portion 111 has a contact avoidance surface 1117. The contact avoidance surface 1117 is continuous to the first lead obverse surface 1111 and the first lead side surface 1113, and is located on the second side z2 in the thickness direction z with respect to the first lead obverse surface 1111. All of the connecting members 31 to 34 overlap with the contact avoidance surface 1117 as viewed in the thickness direction z. Therefore, the semiconductor device A10 can prevent the connecting members 31 to 34 from contacting the die pad portion 111 as compared to the case where the die pad portion 111 is not provided with the contact avoidance surface 1117.

Further, according to the present embodiment, the contact avoidance surface 1117 extends to the respective peripheral ends in the second direction y of the die pad portion 111. Therefore, the semiconductor device A10 can prevent the connecting members 31 to 34 from contacting the die pad portion 111 even in the case where the connecting members 31 to 34 are located near the respective peripheral ends in the second direction y of the die pad portion 111.

Further, according to the present embodiment, as shown in FIGS. 12 to 16, the first lead reverse surface 1112 is exposed from the second resin surface 42. This allows the first lead reverse surface 1112 to have, for example, the heat sink 91 arranged opposed to it. Further, the second sections 1122 are located on the first side z1 in the thickness direction z with respect to the first section 1121. This makes it possible to surface-mount the semiconductor device A10 on the circuit substrate 92 or the like using the second sections 1122. Further, the first lead reverse surface 1112 is separated from the third resin surface 43 in the first direction x. Moreover, the first section 1121 is separated from the second resin surface 42 in the thickness direction z. Therefore, a part of the sealing resin 40 is present between the first lead reverse surface 1112 and the first section 1121. As a result, the first lead 11 can be held more firmly by the sealing resin 40.

Further, according to the present embodiment, the third sections 1123 are parallel (or substantially parallel) to the yz-plane and the second sections 1122 do not extend farther than the third sections 1123 in the first direction x. Therefore, the semiconductor device A10 can reduce the dimension in the first direction x as compared to the case where the second sections 1122 extend farther than the third sections 1123 in the first direction x. Also, since the two second sections 1122 extend outwardly from the third sections 1123 in the second direction y, the semiconductor device A10 can further increase the mounting strength.

Further, according to the present embodiment, the die pad portion 111 has a size in the thickness direction z larger than that of the first section 1121. This allows heat to be transferred to a wider range in the first direction x and the second direction y in the process of heat transfer from the semiconductor element 20 to the first lead reverse surface 1112. Therefore, the heat from the semiconductor element 20 can be dissipated to the heat sink 91 or the like by the wider area of the first lead reverse surface 1112, and the heat dissipation efficiency can be improved.

Further, according to the present embodiment, the groove 49 is formed in the sealing resin 40. This allows the distance along the surface of the sealing resin 40 from the first lead reverse surface 1112 to the second lead 12 (the fourth section 1221), third lead 13 (the seventh section 1321) and fourth lead 14 (the tenth section 1421) (hereinafter referred to as a creepage distance) to be extended.

Note that as for the present embodiment, the case in which the semiconductor element 20 and the semiconductor element 25 are mounted on the first lead obverse surface 1111 of the die pad portion 111 is described, but the present disclosure is not limited thereto. The type and the number of semiconductor elements mounted on the first lead obverse surface 1111 are not limited, and other electronic components may also be mounted.

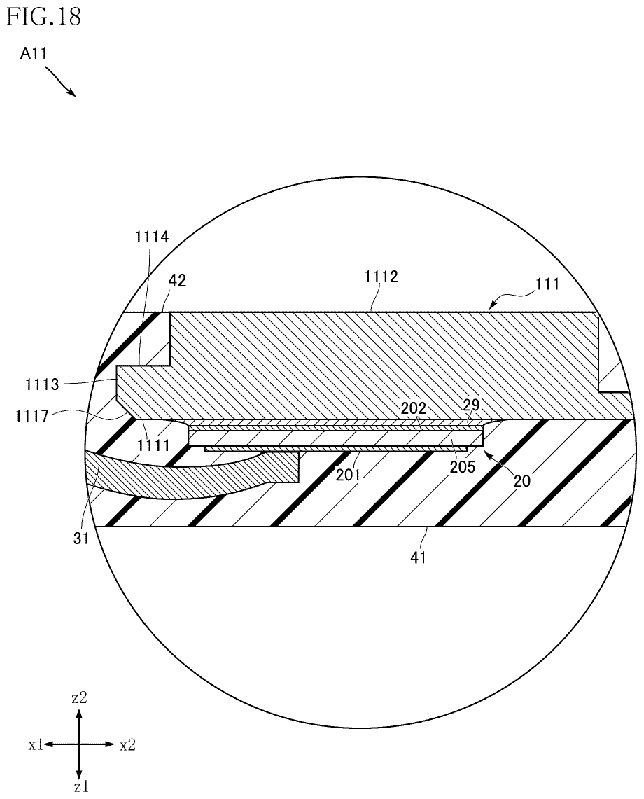

FIGS. 18 to 40 show other embodiments of the present disclosure. Note that in these figures, elements identical or similar to those in the above embodiments are marked with the same symbols as in the above embodiments. Further, the configurations of the respective components of the respective variations and the respective embodiments may be combined with each other as appropriate to the extent that no technical contradiction arises.

### First Variation of First Embodiment

FIG. 18 shows a first variation of the semiconductor device A10. In this variation as a semiconductor device A11, the shape of the contact avoidance surface 1117 is different from the example described above. In the present variation, the contact avoidance surface 1117 is a plane inclined with respect to the first lead obverse surface 1111 and the first lead side surface 1113. According to the present variation as well, the semiconductor device A11 can prevent the connecting members 31 to 34 from contacting the die pad portion 111, and the same effect as that of the semiconductor device A10 is exhibited.

### Second Variation of First Embodiment

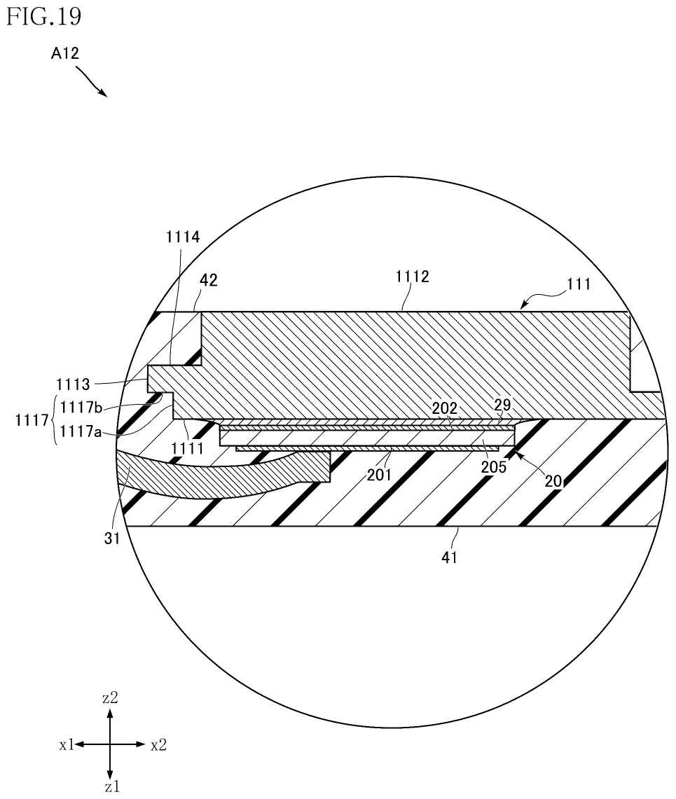

FIG. 19 shows a second variation of the semiconductor device A10. In this variation as a semiconductor device A12, the shape of the contact avoidance surface 1117 is different from those of the examples described above. In the present variation, the contact avoidance surface 1117 includes a first surface 1117a connected to the first lead obverse surface 1111 and parallel (or substantially parallel) to the first lead side surface 1113 and a second surface 1117b connected to the first lead side surface 1113 and parallel (or substantially parallel) to the first lead obverse surface 1111. That is, the contact avoidance surface 1117 forms a staircase-like concave portion in the die pad portion 111 that is recessed from the first lead obverse surface 1111 to the second side z2 in the thickness direction z and recessed from the first lead side surface 1113 to the second side x2 in the first direction x. According to the present variation as well, the semiconductor device A12 can prevent the connecting members 31 to 34 from contacting the die pad portion 111, and the same effect as that of the semiconductor device A10 is exhibited.

### Third Variation of First Embodiment

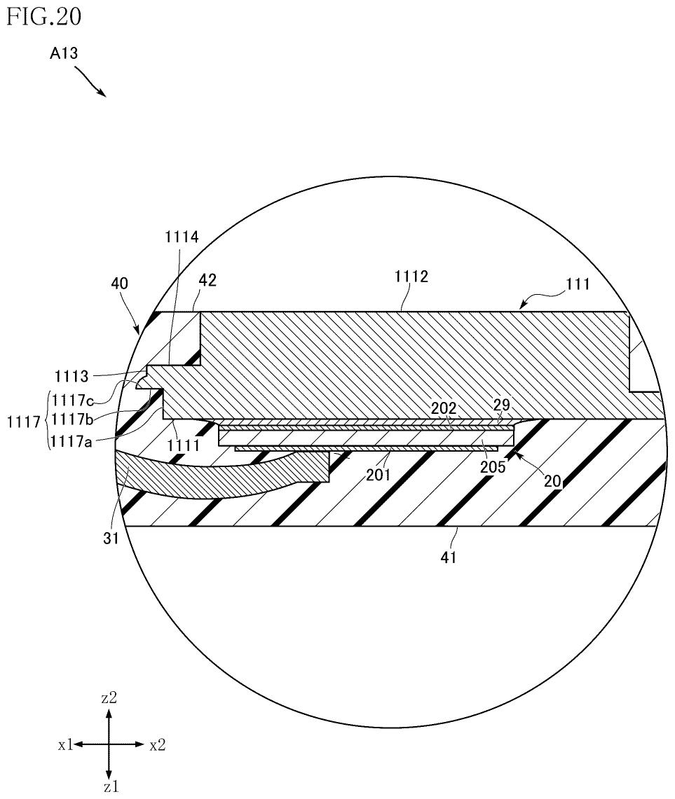

FIG. 20 shows a third variation of the semiconductor device A10. In this variation as a semiconductor device A13, the shape of the contact avoidance surface 1117 is different from those of the examples described above. In the present variation, the contact avoidance surface 1117 includes a first surface 1117a connected to the first lead obverse surface 1111 and parallel (or substantially parallel) to the first lead side surface 1113, a second surface 1117b connected to the first surface 1117a and parallel (or substantially parallel) to the first lead obverse surface 1111, and a third surface 1117c that is a curved surface connected to the second surface 1117b and the first lead side surface 1113. The part between the second surface 1117b and the third surface 1117c is a part that is crushed by the crushing process and thereby extends outwardly. According to the present variation as well, the semiconductor device A13 can prevent the connecting members 31 to 34 from contacting the die pad portion 111, and the same effect as that of the semiconductor device A10 is exhibited.

### Fourth Variation of First Embodiment

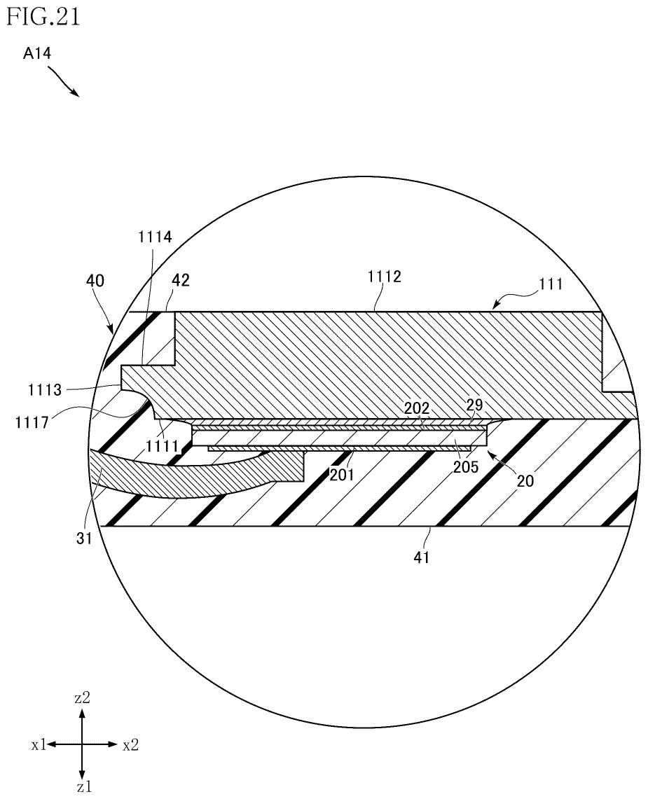

FIG. 21 shows a fourth variation of the semiconductor device A10. In this variation as a semiconductor device A14, the shape of the contact avoidance surface 1117 is different from those of the above examples. In the present variation, the contact avoidance surface 1117 is a concave curvature. The contact avoidance surface 1117 forms, in the die pad portion 111, a concave portion recessed from the first lead obverse surface 1111 to the second side z2 in the thickness direction z and recessed from the first lead side surface 1113 to the second side x2 in the first direction x. The concave portion (the contact avoidance surface 1117) is formed by etching, for example. According to the present variation as well, the semiconductor device A14 can prevent the connecting members 31 to 34 from contacting the die pad portion 111, and the same effect as that of the semiconductor device A10 is exhibited.

### Fifth Variation of First Embodiment

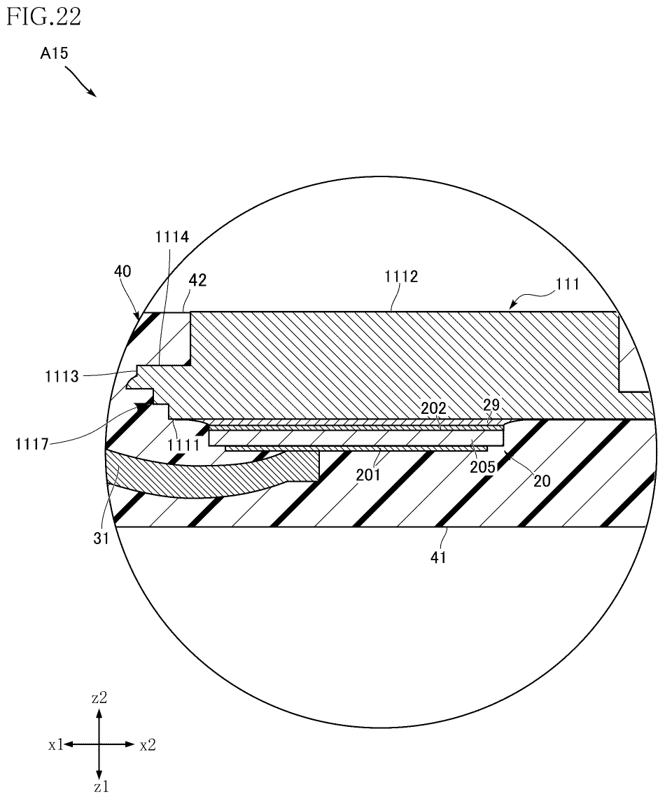

FIG. 22 shows a fifth variation of the semiconductor device A10. In this variation as a semiconductor device A15, the shape of the contact avoidance surface 1117 is different from the examples described above. In the present variation, the contact avoidance surface 1117 is a combination of the contact avoidance surface 1117 according to the second variation and the contact avoidance surface 1117 according to the third variation, and is staircase-shaped. According to the present variation as well, the semiconductor device A15 can prevent the connecting members 31 to 34 from contacting the die pad portion 111, and the same effect as that of the semiconductor device A10 is exhibited.

As understood from the first to fifth variations, the shape of the contact avoidance surface 1117 is not limited. It is sufficient if the contact avoidance surface 1117 is located on the second side z2 in the thickness direction z with respect to the first lead obverse surface 1111 in the thickness direction z.

### Sixth Variation of First Embodiment

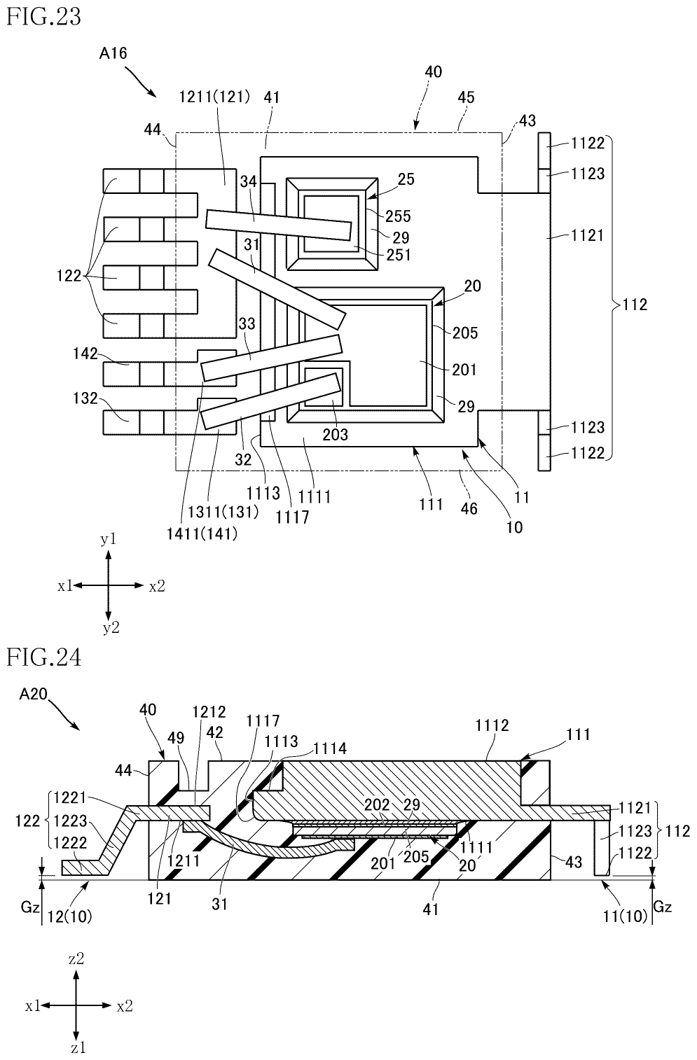

FIG. 23 shows a sixth variation of semiconductor device A10. In this variation as a semiconductor device A16 is different from the above examples in the range in which the contact avoidance surface 1117 is arranged. Note that the respective components of the above first to fifth variations may be arbitrarily combined.

In the present variation, the contact avoidance surface 1117 is inside the die pad portion 111 in the second direction y. That is, the contact avoidance surface 1117 does not extend to the respective peripheral ends in the second direction y of the die pad portion 111. However, the contact avoidance surface 1117 overlaps with all of the connecting members 31 to 34 as viewed in the thickness direction z. The position of the contact avoidance surface 1117 in the second direction y is not limited as long as it overlaps with all of the connecting members 31 to 34 as viewed in the thickness direction z.

According to the present variation as well, the semiconductor device A16 can prevent the connecting members 31 to 34 from contacting the die pad portion 111, and the same effect as that of the semiconductor device A10 is exhibited. Further, according to the present variation, the semiconductor device A16 can reduce the area of the contact avoidance surface 1117 as compared to the case where the contact avoidance surface 1117 extends to the respective peripheral ends in the second direction y of the die pad portion 111, to increase the area of the first lead obverse surface 1111.

### Second Embodiment

FIGS. 24 and 25 show a semiconductor device according to a second embodiment of the present disclosure. A semiconductor device A20 of the present embodiment is different from the first embodiment in the relationships between the first resin surface 41, and the second sections 1122, the fifth sections 1222, the eighth section 1322 and the eleventh section 1422. The configuration and operation of the other parts of the present embodiment are the same as in the first embodiment. Note that the respective components of the above first embodiment and the respective variations may be arbitrarily combined.

In the present embodiment, the second sections 1122, the fifth sections 1222, the eighth section 1322 and the eleventh section 1422 are located on the second side 22 in the thickness direction z (the side toward which the first lead reverse surface 1112 faces) with respect to the first resin surface 41. The first resin surface 41 and the surfaces of the second sections 1122, the fifth sections 1222, the eighth section 1322 and the eleventh section 1422 facing the first side z1 in the thickness direction z are separated by a distance Gz.

According to the present embodiment as well, the semiconductor device A20 can prevent the connecting members 31 to 34 from contacting the die pad portion 111, and the same effect as that of the semiconductor device A10 is exhibited. Further, the first resin surface 41 protrudes by a distance Gz on the first side z1 in the thickness direction z from the second sections 1122, the fifth sections 1222, the eighth section 1322 and the eleventh section 1422. Therefore, in a state of use of the semiconductor device A11 shown in FIG. 25, when the heat sink 91 is pressed against the semiconductor device A20, the first resin surface 41 easily comes into contact with the circuit substrate 92. This can suppress the force applied from the heat sink 91 from acting on the first lead 11, the second lead 12, the third lead 13 and the fourth lead 14 and the semiconductor element 20.

### Third Embodiment

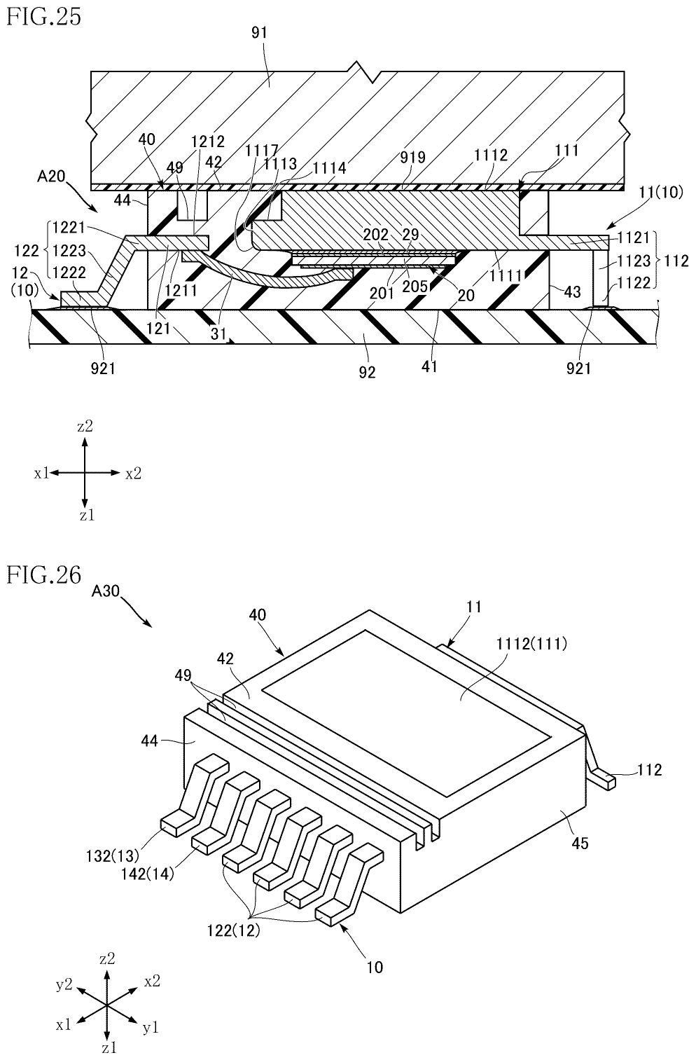

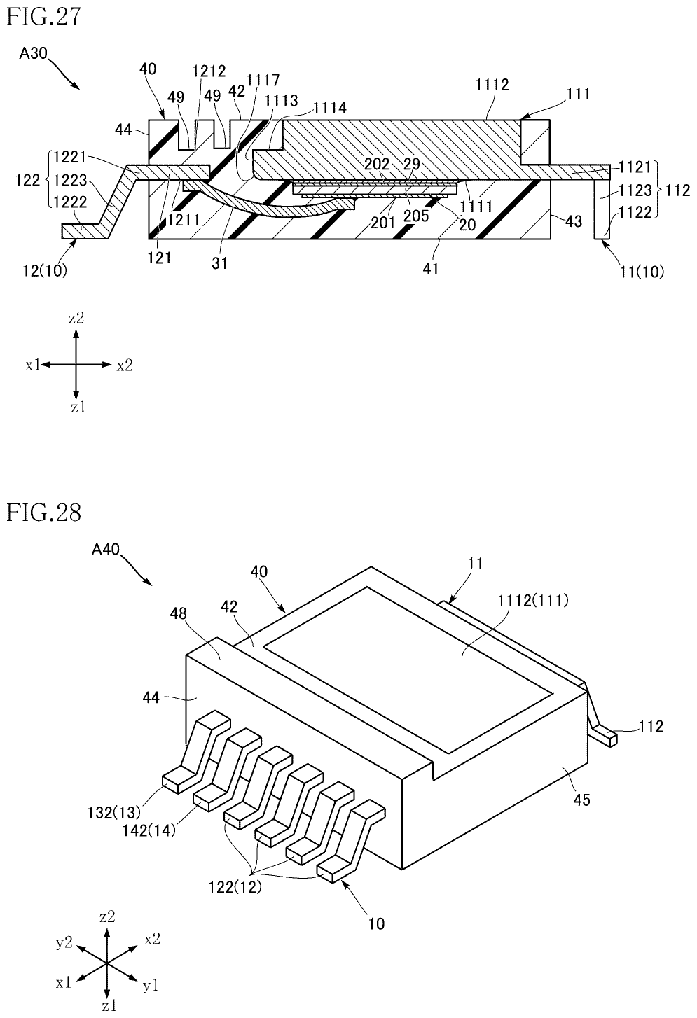

FIGS. 26 and 27 show a semiconductor device according to a third embodiment of the present disclosure. A semiconductor device A30 of the present embodiment is different from the first embodiment in that two grooves 49 are provided in the sealing resin 40. The configuration and operation of the other parts of the present embodiment are the same as in the first embodiment. Note that the respective components of the above first and second embodiments and the respective variations may be arbitrarily combined.

The respective grooves 49 extend in the second direction y and reach the fifth resin surface 45 and the sixth resin surface 46. Further, the two grooves 49 are arranged apart from each other in the first direction x.

According to the present embodiment as well, the semiconductor device A30 can prevent the connecting members 31 to 34 from contacting the die pad portion 111, and the same effect as that of the semiconductor device A10 is exhibited. Further, by having the two grooves 49, the creepage distance between the first lead reverse surface 1112, and the second terminal portions 122, the third terminal portion 132 and the fourth terminal portion 142 can be furthermore extended. As understood from the present embodiment, the number of the groove 49 is not limited in any way.

### Fourth Embodiment

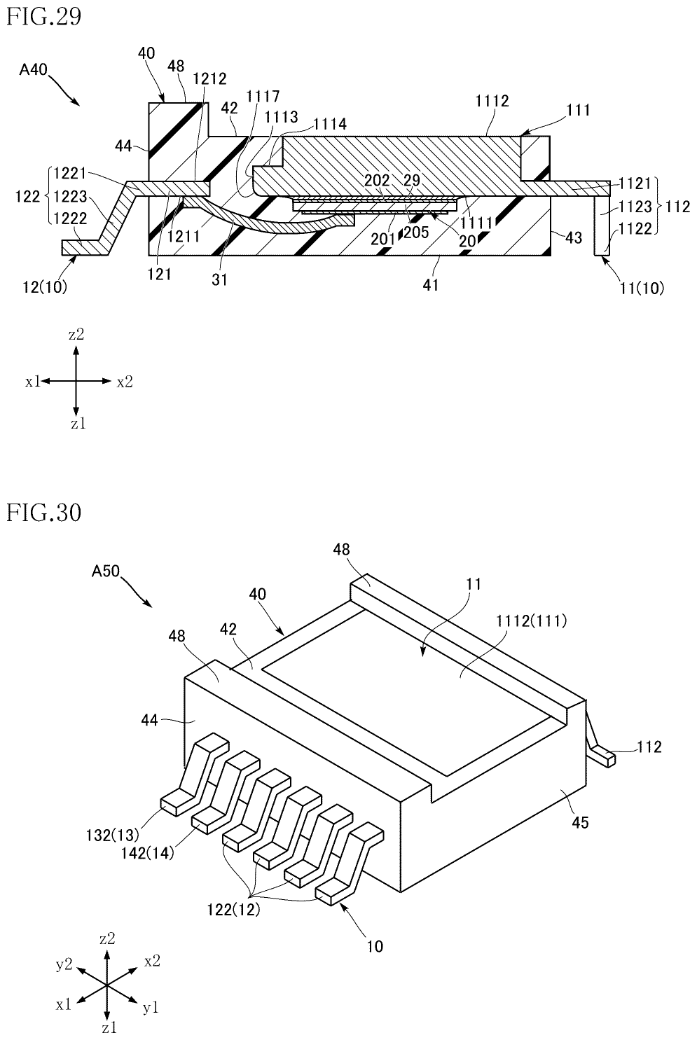

FIGS. 28 and 29 show a semiconductor device according to a fourth embodiment of the present disclosure. A semiconductor device A40 of the present embodiment is different from the first embodiment in that the sealing resin 40 is provided with a protrusion 48. The configuration and operation of the other parts of the present embodiment are the same as in the first embodiment. Note that the respective components of the above first to third embodiments and the respective variations may be arbitrarily combined.

The protrusion 48 protrudes from the second resin surface 42 to the second side z2 in the thickness direction z. The protrusion 48 extends along the second direction y and reaches the fifth resin surface 45 and the sixth resin surface 46. In the illustrated example, the protrusion 48 is arranged at an end on the first side x1 in the first direction x of the sealing resin 40 and borders on the fourth resin surface 44.

According to the present embodiment as well, the semiconductor device A40 can prevent the connecting members 31 to 34 from contacting the die pad portion 111, and the same effect as that of the semiconductor device A10 is exhibited. Further, by having the protrusion 48, the creepage distance between the first lead reverse surface 1112, and the second terminal portions 122, the third terminal portion 132 and the fourth terminal portion 142 can be extended.

### Fifth Embodiment

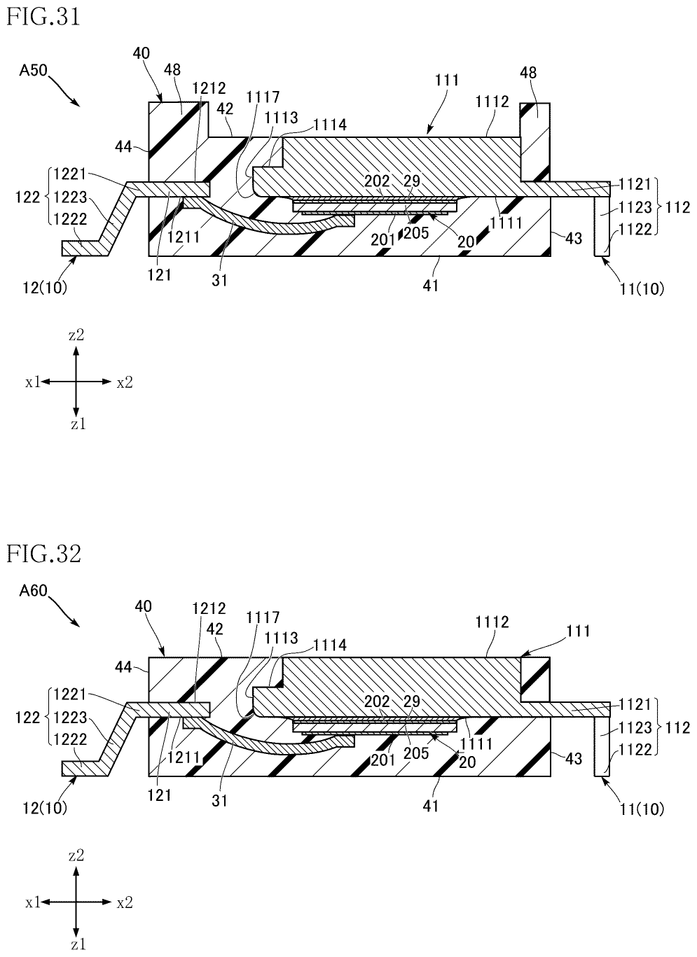

FIGS. 30 and 31 show a semiconductor device according to a fifth embodiment of the present disclosure. A semiconductor device A50 of the present embodiment is different from the first embodiment in that two protrusions 48 are provided in the sealing resin 40. The configuration and operation of the other parts of the present embodiment are the same as in the first embodiment. Note that the respective components of the above first to fourth embodiments and the respective variations may be arbitrarily combined.

Each of the protrusions 48 protrudes from the second resin surface 42 to the second side z2 in the thickness direction z. Each of the protrusions 48 extends along the second direction y and reaches the fifth resin surface 45 and the sixth resin surface 46. The two protrusions 48 are arranged apart from each other across the first lead reverse surface 1112 in the first direction x. One protrusion 48 borders on the fourth resin surface 44. The other protrusion 48 borders on the third resin surface 43.

According to the present embodiment as well, the semiconductor device A50 can prevent the connecting members 31 to 34 from contacting the die pad portion 111, and the same effect as that of the semiconductor device A10 is exhibited. Further, by having the two protrusions 48, the creepage distance between the first lead reverse surface 1112, and the second terminal portions 122, the third terminal portion 132 and the fourth terminal portion 142 can be furthermore extended. As understood from the present embodiment, the number of the protrusion 48 is not limited in any way.

### Sixth Embodiment

FIG. 32 shows a semiconductor device according to a sixth embodiment of the present disclosure. A semiconductor device A60 of the present embodiment is different from the first embodiment in that the sealing resin 40 does not have the groove 49. The configuration and operation of the other parts of the present embodiment are the same as in the first embodiment. Note that the respective components of the above first to fifth embodiments and the respective variations may be arbitrarily combined. According to the present embodiment as well, the semiconductor device A60 can prevent the connecting members 31 to 34 from contacting the die pad portion 111 and the same effect as that of the semiconductor device A10 is exhibited. Further, as understood from the present embodiment, the sealing resin 40 may be configured without the protrusion 48 and the groove 49.

### Seventh Embodiment

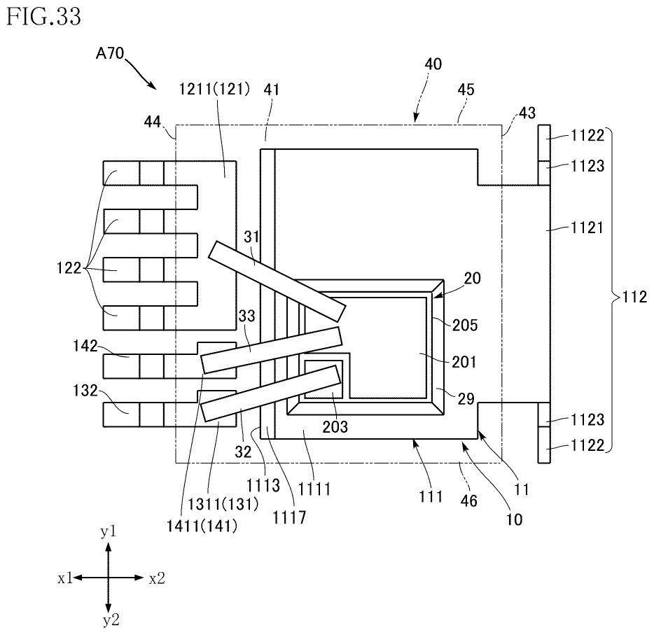

FIG. 33 shows a semiconductor device according to a seventh embodiment of the present disclosure. A semiconductor device A70 of the present embodiment is different from the first embodiment in that it is not provided with the semiconductor element 25. The configuration and operation of the other parts of the present embodiment are the same as in the first embodiment. Note that the components of the above first to sixth embodiments and the respective variations may be arbitrarily combined. According to the present embodiment as well, the semiconductor device A70 can prevent the connecting members 31 to 34 from contacting the die pad portion 111, and the same effect as that of the semiconductor device A10 is exhibited. Further, as understood from the present embodiment, the type and number of electronic components mounted on the first lead obverse surface 1111 are not limited.

### Eighth Embodiment

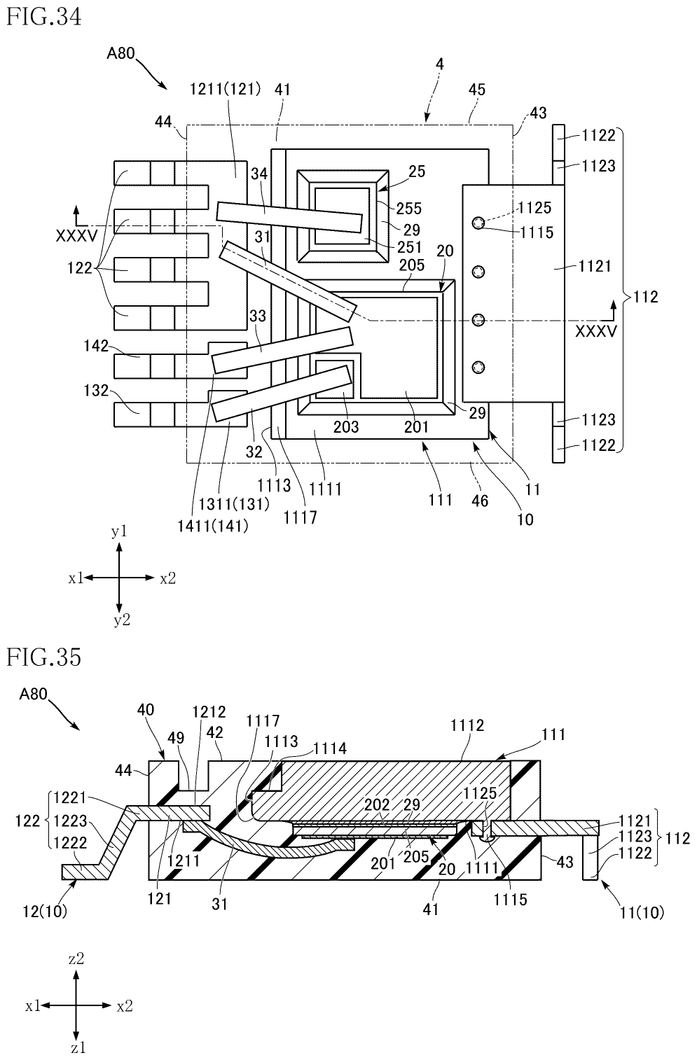

FIGS. 34 and 35 show a semiconductor device according to an eighth embodiment of the present disclosure. A semiconductor device A80 of the present embodiment is different from the first embodiment in that the first lead 11 is formed by bonding the die pad portion 111 and the first terminal portion 112. The configuration and operation of the other parts of the present embodiment are the same as in the first embodiment. Note that the respective components of the above first to seventh embodiments and the respective variations may be arbitrarily combined.

The first lead 11 is formed by bonding the die pad portion 111 and the first terminal portion 112, which were separate components. In the present embodiment, the die pad portion 111 has a plurality of engagement portions 1115 protruding from the first lead obverse surface 1111 in the thickness direction z and engaged with the engagement holes 1125 described below of the first terminal portion 112. The plurality of engagement portions 1115 are arranged in line in the second direction y. The first section 1121 of the first terminal portion 112 is bonded to the die pad portion 111. In the present embodiment, the first section 1121 is bonded to the first lead obverse surface 1111 of the die pad portion 111. The first section 1121 has a plurality of engagement holes 1125 penetrating in the thickness direction z. The plurality of engagement holes 1125 are arranged in line in the second direction y. The first section 1121 is caulked and bonded to the die pad portion 111. Specifically, the first section 1121 is inserted in the engagement holes 1125 with the engagement portions 1115 of the die pad portion 111. Then, pressure is applied by the mold from the tip side of the engagement portions 1115 while heat is applied. As a result, the tip portions of the engagement portions 1115 are crushed to engage the engagement holes 1125, and further the peripheral surfaces of the engagement portions 1115 adhere to the inner surfaces of the engagement holes 1125.

According to the present embodiment as well, the semiconductor device A80 can prevent the connecting members 31 to 34 from contacting the die pad portion 111, and the same effect as that of the semiconductor device A10 is exhibited. Further, according to the present embodiment, the first lead 11 is formed by bonding the die pad portion 111 and the first terminal portion 112, which were separate members. Therefore, it is possible to form a first lead 11 having a die pad portion 111 and a first terminal portion 112 that are different greatly in size in the thickness direction z. In a case to form the first lead 11 using a lead frame of an irregular strip, there is a limitation on the dimension in the thickness direction z of the die pad portion 111. However, the semiconductor device A80 can increase the dimension in the thickness direction z of the die pad portion 111 regardless of this limitation. Further, the first lead 11 is formed by inserting the respective engagement portions 1115 of the die pad portion 111 into the respective engagement holes 1125 of the first section 1121 of the first terminal portion 112, and by caulking and bonding. As a result, the first lead 11 is an integral member with the first terminal portion 112 firmly bonded to the die pad portion 111. Therefore, it is not necessary to use other members such as bonding material in bonding the die pad portion 111 and the first terminal portion 112.

Note that the method of bonding the die pad portion 111 and the first terminal portion 112 is not limited. The die pad portion 111 and the first terminal portion 112 may be bonded by another mechanical bonding that uses, for example, screws, rivets, and the like. Further, the die pad portion 111 and the first terminal portion 112 may be bonded, for example, by ultrasonic bonding, or by bonding materials such as solder, silver (Ag) paste, sintered silver, or by other metallurgical bonding such as welding, and so forth. Further, as for the present embodiment, the case in which the first terminal portion 112 is bonded to the first lead obverse surface 1111 of the die pad portion 111 is described, but the present disclosure is not limited to this case. The bonding position of the first terminal portion 112 bonded to the die pad portion 111 is not limited in any way.

### Ninth Embodiment

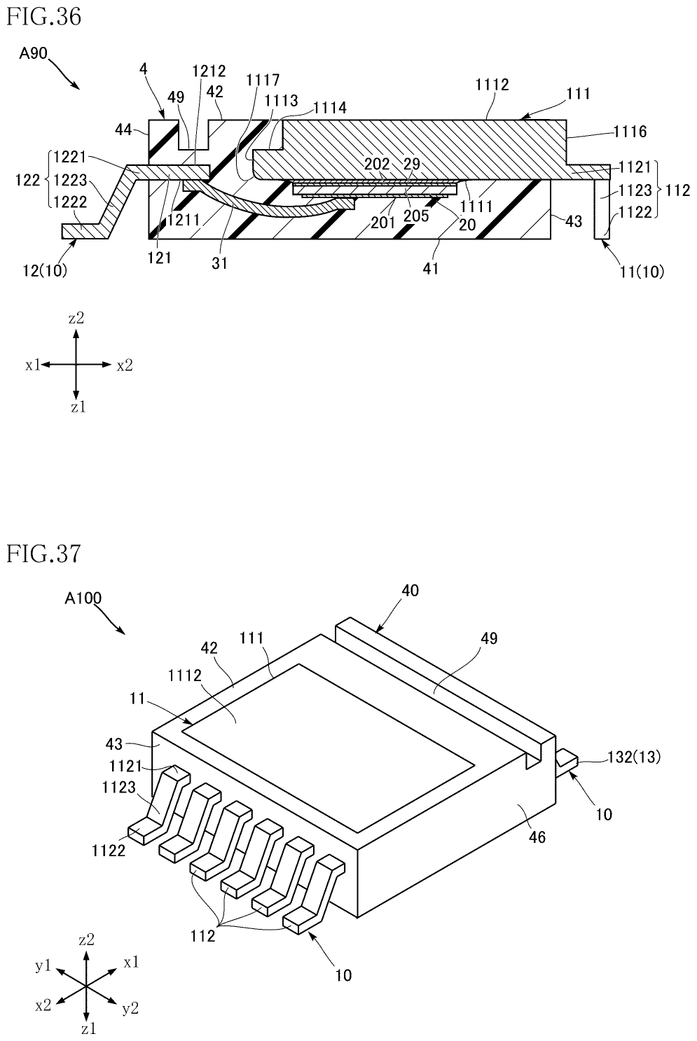

FIG. 36 shows a semiconductor device according to a ninth embodiment of the present disclosure. A semiconductor device A90 of the present embodiment is different from the embodiments described above in the configuration of the first lead 11. The configuration and operation of the other parts of the present embodiment are the same as in the first embodiment. Note that the respective components of the above first to eighth embodiments and the respective variations may be arbitrarily combined.

The die pad portion 111 has a first lead second side surface 1116. The first lead second side surface 1116 is a surface located between the first lead obverse surface 1111 and the first lead reverse surface 1112 in the thickness direction z and facing the second side x2 in the first direction x. In the present embodiment, the first lead second side surface 1116 is located on the second side x2 in the first direction x with respect to the third resin surface 43. That is, the first lead second side surface 1116 has a part located on the second side x2 in the first direction x with respect to the third resin surface 43 as viewed in the thickness direction z.

According to the present embodiment as well, the semiconductor device A90 can prevent the connecting members 31 to 34 from contacting the die pad portion 111, and the same effect as that of the semiconductor device A10 is exhibited. Further, according to the present embodiment, the area of the first lead reverse surface 1112 opposed to the heat sink 91 can be expanded, as the first lead reverse surface 1112 has a portion that extends farther than the third resin surface 43 toward the second side x2 in the first direction x. Therefore, the heat dissipation efficiency from the semiconductor device A90 to the heat sink 91 can be increased.

### Tenth Embodiment

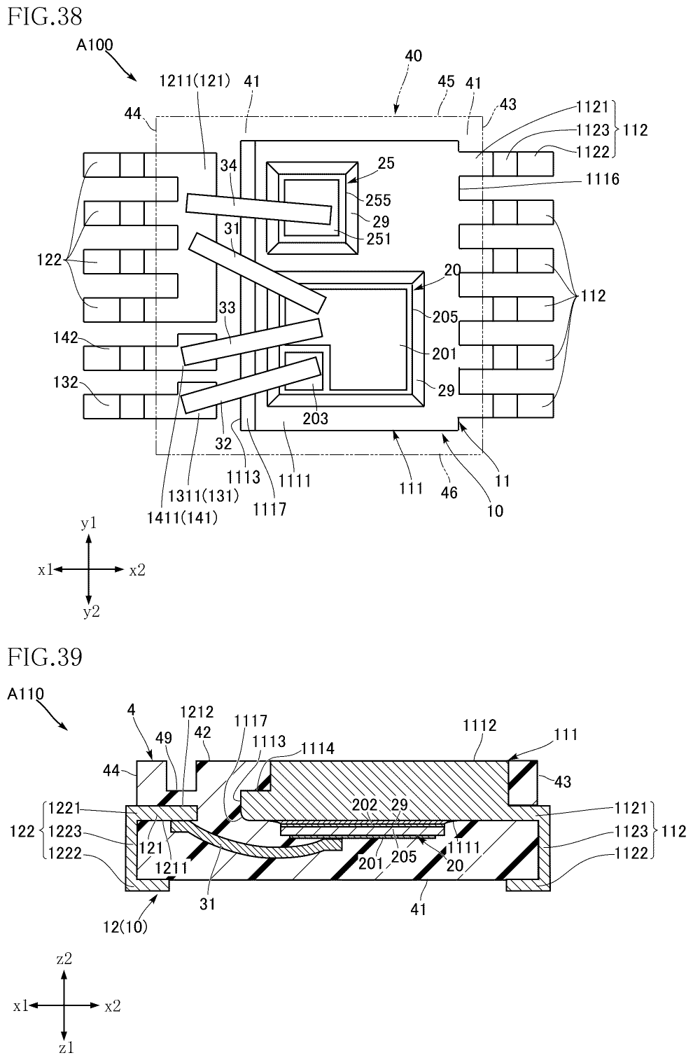

FIGS. 37 and 38 show a semiconductor device according to a tenth embodiment of the present disclosure. A semiconductor device A100 of the present embodiment is different from the embodiments described above in the configuration of the first terminal portion 112. The configuration and operation of the other parts of the present embodiment are the same as in the first embodiment. Note that the respective components of the above first to ninth embodiments and the respective variations may be arbitrarily combined.

The first lead 11 of the present embodiment has a plurality of first terminal portions 112. The plurality of first terminal portions 112 are arranged in line in the second direction y. Each of the first terminal portions 112 has a first section 1121, a second section 1122, and a third section 1123.

The first section 1121 is connected to the die pad portion 111. The first section 1121 extends from the first lead second side surface 1116 of the die pad portion 111 to the second side x2 in the first direction x and is parallel (or substantially parallel) to the xy plane in the illustrated example. The first section 1121 penetrates the third resin surface 43. The shape of the first section 1121 is not limited in any way, and in the illustrated example it is rectangular as viewed in the thickness direction z.

The second section 1122 is located on the first side z1 in the thickness direction z with respect to the first section 1121. The second section 1122 is used when the semiconductor device A100 is surface-mounted on a circuit substrate or the like. The second section 1122 is shaped to extend along the first direction x.

The third section 1123 is interposed between the first section 1121 and the second section 1122. The third section 1123 extends from the first section 1121 to the first side z1 in the thickness direction z. In the illustrated example, the third section 1123 is inclined with respect to the thickness direction z (the yz plane). The shape of the third section 1123 is not limited in any way, and in the illustrated example it is rectangular as viewed in the first direction x.

According to the present embodiment as well, the semiconductor device A100 can prevent the connecting members 31 to 34 from contacting the die pad portion 111, and the same effect as that of the semiconductor device A10 is exhibited. Further, the first lead 11 has a plurality of first terminal portions 112. This can increase the mounting strength of the semiconductor device A100. As understood from the present embodiment, the configuration of the first terminal portion 112 is not limited in any way.

### Eleventh Embodiment

FIG. 39 shows a semiconductor device according to an eleventh embodiment of the present disclosure. A semiconductor device A110 of the present embodiment is different from the embodiments described above in the shapes of the first terminal portion 112, the second terminal portions 122, the third terminal portion 132 and the fourth terminal portion 142. The configuration and operation of the other parts of the present embodiment are the same as in the first embodiment. Note that the respective components of the above first to tenth embodiments and the respective variations may be arbitrarily combined.

Regarding the first terminal portion 112 of the present embodiment, the third sections 1123 extend from an end of the first section 1121 on the second side x2 of the first direction x toward the first side z1 in the thickness direction z along the third resin surface 43. Further, the second sections 1122 extend from ends of the third sections 1123 on the first side z1 of the first direction z along the first resin surface 41 toward the first side x1 in the first direction x. Further, regarding the second terminal portions 122 of the present embodiment, the sixth sections 1223 extend from ends of the fourth sections 1221 on the first side x1 of the first direction x along the fourth resin surface 44 toward the first side z1 in the thickness direction z. Further, the fifth sections 1222 extend from ends of the sixth sections 1223 on the first side z1 of the thickness direction z along the first resin surface 41 toward the second side x2 in the first direction x. Similarly, although not shown in the figure, regarding the third terminal portion 132 of the present embodiment, the ninth section 1323 extends from an end of the seventh section 1321 on the first side x1 of the first direction x along the fourth resin surface 44 toward the first side z1 in the thickness direction z. Further, the eighth section 1322 extends from an end of the ninth section 1323 on the first side z1 of the thickness direction z along the first resin surface 41 toward the second side x2 in the first direction x. Further, regarding the fourth terminal portion 142 of the present embodiment, the twelfth section 1423 extends from an end of the tenth section 1421 on the first side x1 of the first direction x along the fourth resin surface 44 toward the first side z1 in the thickness direction z. Further, the eleventh section 1422 extends from an end of the twelfth section 1423 on the first side z1 of the thickness direction z along the first resin surface 41 toward the second side x2 in the first direction x.

According to the present embodiment as well, the semiconductor device A110 can prevent the connecting members 31 to 34 from contacting the die pad portion 111, and the same effect as that of the semiconductor device A10 is exhibited. Further, according to the present embodiment, the second sections 1122, the fifth sections 1222, the eighth section 1322 and the eleventh section 1422 extend inwardly in the first direction x, therefore, as compared to the case where they extend outwardly in the first direction x (so-called a gull-wing shape), the mounting area (the dimension in the first direction x) of the semiconductor device A110 can be reduced. Further, as understood from the present embodiment, the shapes of the first terminal portion 112, the second terminal portions 122, the third terminal portion 132 and the fourth terminal portion 142 are not limited in any way.

### Twelfth Embodiment

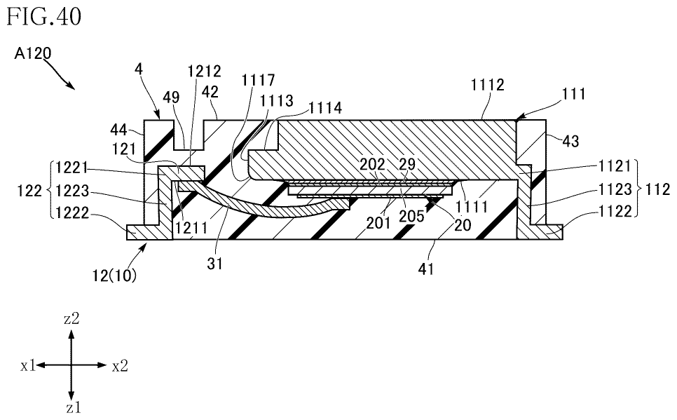

FIG. 40 shows a semiconductor device according to a twelfth embodiment of the present disclosure. A semiconductor device A120 of the present embodiment is different from the embodiments described above in the configuration of the first terminal portion 112, the second terminal portions 122, the third terminal portion 132 and the fourth terminal portion 142. The configuration and operation of the other parts of the present embodiment are the same as in the first embodiment. Note that the respective components of the above first to eleventh embodiments and the respective variations may be arbitrarily combined.

In the present embodiment, regarding the first terminal portion 112, the first section 1121 does not penetrate the third resin surface 43, the third sections 1123 extend in the scaling resin 40 in the thickness direction z, and the second sections 1122 are exposed from the first resin surface 41. Further, regarding the second terminal portions 122, the fourth sections 1221 do not penetrate the fourth resin surface 44, the sixth sections 1223 extend in the sealing resin 40 in the thickness direction z, and the fifth sections 1222 are exposed from the first resin surface 41. Further, although not shown in the figure, regarding the third terminal portion 132, the seventh section 1321 does not penetrate the fourth resin surface 44, the ninth section 1323 extends in the scaling resin 40 in the thickness direction z, and the eighth section 1322 is exposed from the first resin surface 41. Similarly, regarding the fourth terminal portion 142, the tenth section 1421 does not penetrate the fourth resin surface 44, the twelfth section 1423 extends in the scaling resin 40 in the thickness direction z, and the eleventh section 1422 is exposed from the first resin surface 41.

According to the present embodiment as well, the semiconductor device A120 can prevent the connecting members 31 to 34 from contacting the die pad portion 111 and the same effect as that of the semiconductor device A10 is exhibited. Further, the mounting area (the dimension in the first direction x) of the semiconductor device A120 can be reduced as compared to the case where the first terminal portion 112, the second terminal portions 122, the third terminal portion 132 and the fourth terminal portion 142 protrude in the first direction x, penetrating the third resin surface 43 or the fourth resin surface 44. As understood from the present embodiment, the configuration of the first terminal portion 112, the second terminal portions 122, the third terminal portion 132 and the fourth terminal portion 142 is not limited in any way.

The semiconductor devices according to the present disclosure are not limited to the aforementioned embodiments. The specific configuration of each part of the semiconductor devices according to the present disclosure can be designed and modified in various ways. The present disclosure includes the embodiments described in the following clauses.

Clause 1.

A semiconductor device comprising:

a semiconductor element (20);

a first lead (11) including a die pad portion (111), the die pad portion having a first lead obverse surface (1111) facing a first side (z1) in a thickness direction (z) and on which the semiconductor element is mounted, a first lead reverse surface (1112) facing a second side (z2) in the thickness direction (z), and a first lead side surface (1113) facing a first side (x1) in a first direction (x) orthogonal to the thickness direction;

a second lead (12) arranged apart from the die pad portion toward the first side in the first direction; and

a wire (31) conductively bonded to the semiconductor element and the second lead,

wherein the die pad portion is further provided with a contact avoidance surface (1117) connected to the first lead obverse surface and the first lead side surface, and

the contact avoidance surface overlaps with the wire as viewed in the thickness direction, and is located on the second side in the thickness direction with respect to the first lead obverse surface.

Clause 2.

The semiconductor device according to Clause 1, wherein the contact avoidance surface is a curvature that is convex outwardly.

Clause 3, the fourth variation of the first embodiment, FIG. 21.

The semiconductor device according to Clause 1, wherein the contact avoidance surface is a concave curvature.

Clause 4, the first variation of the first embodiment, FIG. 18.

The semiconductor device according to Clause 1, wherein the contact avoidance surface is a plane inclined with respect to the first lead obverse surface and the first lead side surface.

Clause 5, the second variation of the first embodiment, FIG. 19.

The semiconductor device according to Clause 1, wherein the contact avoidance surface includes a first surface (1117a) connected to the first lead obverse surface and parallel to the first lead side surface, and a second surface (1117b) connected to the first lead side surface and parallel to the first lead obverse surface.

Clause 6.

The semiconductor device according to any one of Clauses 1 to 5, wherein the contact avoidance surface is inside the die pad portion in a second direction (y) orthogonal to the thickness direction and the first direction.

Clause 7.

The semiconductor device according to any one of Clauses 1 to 5, wherein the contact avoidance surface extends to a peripheral end of the die pad portion in a second direction orthogonal to the thickness direction and the first direction.

Clause 8.

The semiconductor device according to any one of Clauses 1 to 7, wherein the second lead is curved toward the first side in the thickness direction.

Clause 9, FIG. 13.

The semiconductor device according to any one of Clauses 1 to 8, wherein in the first direction, a distance (L1) between the first lead side surface and a bonding position of the wire with the semiconductor element is equal to or more than one third of a dimension (L2) of the first lead obverse surface.

Clause 10.

The semiconductor device according to any one of Clauses 1 to 9, further comprising a sealing resin (4) having a first resin surface (41) and a second resin surface (42),

wherein the first resin surface faces the first side in the thickness direction, the second resin surface faces the second side in the thickness direction, and the sealing resin covers the semiconductor element and a part of the die pad portion, and

wherein the first lead reverse surface is exposed from the second resin surface.

Clause 11, FIG. 13.

The semiconductor device according to Clause 10, wherein a distance (L4) between the first resin surface and the first lead obverse surface is equal to or less than four times a diameter (L3) of the wire.

Clause 12.

The semiconductor device according to Clause 10 or 11,

wherein the first lead further includes a first terminal portion (112),

the first terminal portion is provided with a first section (1121) connected to the die pad portion, a second section (1122) located on the first side in the thickness direction with respect to the first section and used for arranging the semiconductor device, and a third section (1123) interposed between the first section and the second section, and

the second section extends from the third section outwardly in a second direction orthogonal to the thickness direction and the first direction.

Clause 12-1, the eighth embodiment, FIGS. 34 and 35.

The semiconductor device according to Clause 10 or 11,

wherein the first lead further includes a first terminal portion,

the first terminal portion is provided with a first section connected to the die pad portion, a second section located on the first side in the thickness direction with respect to the first section and used for arranging the semiconductor device, and a third section interposed between the first section and the second section.

Clause 12-2.

The semiconductor device according to Clause 12-1,

wherein the die pad portion further has an engagement portion (1115),

the first section has an engagement hole (1125) to engage with the engagement portion, and

the engagement portion is caulked to the engagement hole.

Clause 12-3.

The semiconductor device according to Clause 12-1 or 12-2,

wherein the first section is bonded to the first lead obverse surface.

Clause 13.

The semiconductor device according to Clause 12,

wherein the second lead is provided with a second pad portion (121) and a second terminal portion (122) connected to the second pad portion,

the second terminal portion is provided with a fourth section (1221) connected to the second pad portion, a fifth section (1222) located on the first side in the thickness direction with respect to the fourth section and used for arranging the semiconductor device, and a sixth section (1223) interposed between the fourth section and the fifth section, and

the sealing resin further has a third resin surface (43) facing the first side in the first direction and a fourth resin surface (44) facing a second side in the first direction.

Clause 14.

The semiconductor device according to Clause 13,

wherein the first section penetrates the third resin surface and is separated from the second resin surface in the thickness direction, and

the fourth section penetrates the fourth resin surface and is separated from the second resin surface in the thickness direction.

Clause 15, the second embodiment, FIGS. 24 and 25.

The semiconductor device according to Clause 13 or 14,

wherein the second section and the fifth section are located on the second side in the thickness direction with respect to the first resin surface.

Clause 16.

The semiconductor device according to any one of Clauses 13 to 15,

wherein the second pad portion has a second lead obverse surface facing the first side in the thickness direction, and

a surface of the first section on the first side in the thickness direction, the first lead obverse surface, a surface of the fourth section on the first side in the thickness direction and the second lead obverse surface are at a same position in the thickness direction.

Clause 17, the eleventh embodiment, FIG. 39.

The semiconductor device according to any one of Clauses 13 to 16,

wherein the third section and the sixth section extend in the sealing resin in the thickness direction, and

the second section and the fifth section are exposed from the first resin surface.

Clause 18.

The semiconductor device according to any one of Clauses 10 to 17,

wherein the sealing resin has a groove (49) recessed from the second resin surface in the thickness direction.

Clause 19, the fourth embodiment, FIGS. 28 and 29.

The semiconductor device according to any one of Clauses 10 to 18,

wherein the sealing resin has a protrusion (48) protruding from the second resin surface in the thickness direction.

### REFERENCE NUMERALS

A10, A11, A12, A13, A14, A15, A16, A20, A30, A40, A50, A60, A70, A80, A90, A100, A110, A120: Semiconductor device
10: Conductive member 11: First lead
12: Second lead 13: Third lead
14: Fourth lead 20, 25: Semiconductor element
29: Bonding layer 31, 32, 33, 34: Connecting member
31a: Bonding position 40: Sealing resin
41: First resin surface 42: Second resin surface
43: Third resin surface 44: Fourth resin surface
45: Fifth resin surface 46: Sixth resin surface
48: Protrusion 49: Groove
91: Heat sink 92: Circuit substrate
111: Die pad portion 112: First terminal portion
121: Second pad portion 122: Second terminal portion
131: Third pad portion 132: Third terminal portion
141: Fourth pad portion 142: Fourth terminal portion
201: First electrode 202: Second electrode
203: Third electrode 205: Semiconductor layer
251: First electrode 252: Second electrode
255: Semiconductor layer 919: Sheet material
921: Solder 1111: First lead obverse surface
1112: First lead reverse surface 1113: First lead side surface
1114: First intermediate surface 1115: Engagement portion
1116: First lead second side surface 1117: Contact avoidance surface
1117a: First surface 1117b: Second surface
1117c: Third surface 1121: First section
1122: Second section 1123: Third section
1125: Engagement hole 1211: Second lead obverse surface
1212: Second lead reverse surface 1221: Fourth section
1222: Fifth section 1223: Sixth section
1311: Third lead obverse surface 1312: Third lead reverse surface
1321: Seventh section 1322: Eighth section
1323: Ninth section 1411: Fourth lead obverse surface
1412: Fourth lead reverse surface 1421: Tenth section
1422: Eleventh section 1423: Twelfth section

1. A semiconductor device comprising:
a semiconductor element;
a first lead including a die pad portion, the die pad portion having a first lead obverse surface facing a first side in a thickness direction and on which the semiconductor element is mounted, a first lead reverse surface facing a second side in the thickness direction, and a first lead side surface facing a first side in a first direction orthogonal to the thickness direction;
a second lead arranged apart from the die pad portion toward the first side in the first direction; and
a wire conductively bonded to the semiconductor element and the second lead,
wherein the die pad portion is further provided with a contact avoidance surface connected to the first lead obverse surface and the first lead side surface, and
the contact avoidance surface overlaps with the wire as viewed in the thickness direction, and is located on the second side in the thickness direction with respect to the first lead obverse surface.

2. The semiconductor device according to claim 1, wherein the contact avoidance surface is a curvature that is convex outwardly.

3. The semiconductor device according to claim 1, wherein the contact avoidance surface is a concave curvature.

4. The semiconductor device according to claim 1, wherein the contact avoidance surface is a plane inclined with respect to the first lead obverse surface and the first lead side surface.

5. The semiconductor device according to claim 1, wherein the contact avoidance surface includes a first surface connected to the first lead obverse surface and parallel to the first lead side surface, and a second surface connected to the first lead side surface and parallel to the first lead obverse surface.

6. The semiconductor device according to claim 1, wherein the contact avoidance surface is inside the die pad portion in a second direction orthogonal to the thickness direction and the first direction.

7. The semiconductor device according to claim 1, wherein the contact avoidance surface extends to a peripheral end of the die pad portion in a second direction orthogonal to the thickness direction and the first direction.

8. The semiconductor device according to claim 1, wherein the second lead is curved toward the first side in the thickness direction.

9. The semiconductor device according to claim 1, wherein in the first direction, a distance between the first lead side surface and a bonding position of the wire with the semiconductor element is equal to or more than one third of a dimension of the first lead obverse surface.

10. The semiconductor device according to claim 1, further comprising a sealing resin having a first resin surface and a second resin surface,
wherein the first resin surface faces the first side in the thickness direction, the second resin surface faces the second side in the thickness direction, and the sealing resin covers the semiconductor element and a part of the die pad portion, and
wherein the first lead reverse surface is exposed from the second resin surface.

11. The semiconductor device according to claim 10, wherein a distance between the first resin surface and the first lead obverse surface is equal to or less than four times a diameter of the wire.

12. The semiconductor device according to claim 10,
wherein the first lead further includes a first terminal portion,
the first terminal portion is provided with a first section connected to the die pad portion, a second section located on the first side in the thickness direction with respect to the first section and used for arranging the semiconductor device, and a third section interposed between the first section and the second section, and
the second section extends from the third section outwardly in a second direction orthogonal to the thickness direction and the first direction.

13. The semiconductor device according to claim 12,
wherein the second lead is provided with a second pad portion and a second terminal portion connected to the second pad portion,
the second terminal portion is provided with a fourth section connected to the second pad portion, a fifth section located on the first side in the thickness direction with respect to the fourth section and used for arranging the semiconductor device, and a sixth section interposed between the fourth section and the fifth section, and
the sealing resin further has a third resin surface facing the first side in the first direction and a fourth resin surface facing a second side in the first direction.

14. The semiconductor device according to claim 13,
wherein the first section penetrates the third resin surface and is separated from the second resin surface in the thickness direction, and
the fourth section penetrates the fourth resin surface and is separated from the second resin surface in the thickness direction.

15. The semiconductor device according to claim 13,
wherein the second section and the fifth section are located on the second side in the thickness direction with respect to the first resin surface.

16. The semiconductor device according to claim 13,
wherein the second pad portion has a second lead obverse surface facing the first side in the thickness direction, and
a surface of the first section on the first side in the thickness direction, the first lead obverse surface, a surface of the fourth section on the first side in the thickness direction and the second lead obverse surface are at a same position in the thickness direction.
